(19) United States
(12) Patent Application Publication
(10) Pub. No.: US 2026/0156887 A1
(43) Pub. Date: Jun. 4, 2026

(54) Silicon Carbide Based Structures and Devices with Heterodoped Layer(s)

(71) Applicant: Wolfspeed, Inc., Durham, NC (US)

(72) Inventors: Woongsun Kim, Cary, NC (US); Julio Garceran, Cary, NC (US); Sei-Hyung Ryu, Cary, NC (US); Thomas Albert Kuhr, Durham, NC (US)

(21) Appl. No.: 19/034,001

(22) Filed: Jan. 22, 2025

Related U.S. Application Data
(63) Continuation-in-part of application No. 18/968,523, filed on Dec. 4, 2024.

(51) Int. Cl. H10D 62/832; H10D 8/60; H10D 12/00; H10D 30/66; H10D 62/60

(52) U.S. Cl. CPC H10D 62/8325; H10D 8/60; H10D 12/481; H10D 30/668; H10D 62/60

(57) ABSTRACT

An example power semiconductor device includes a silicon carbide semiconductor structure. The example power semiconductor device includes at least one heterodoped layer in the silicon carbide semiconductor structure. In some implementations, the heterodoped layer includes a first layer having a first dopant concentration of a first conductivity type in a range of about 1×10¹⁷/cm³ to about 2×10²¹/cm³. The heterodoped layer includes a second layer having a second dopant concentration of the first conductivity type that is less than the first dopant concentration of the first layer. In some examples, the second layer may be undoped.

### PRIORITY CLAIM

The present application is a continuation in part of and claims the benefit of priority of U.S. patent application Ser. No. 18/968,523, filed on Dec. 4, 2024, which is incorporated herein by reference.

### FIELD

The present disclosure relates generally to semiconductor devices.

### BACKGROUND

Silicon carbide (SiC) exhibits many attractive electrical and thermophysical properties. Silicon carbide is especially useful due to its physical strength and high resistance to chemical attack. Silicon carbide also has excellent electronic properties, including radiation hardness, high breakdown field, a relatively wide band gap, high saturated electron drift velocity, high temperature operation, and absorption and emission of high energy photons in the blue, violet, and ultraviolet regions of the spectrum. Some of the properties of SiC make it suitable for the fabrication of high-power density solid state devices.

Power semiconductor devices are used to carry large currents and support high voltages. A wide variety of power semiconductor devices are known in the art including, for example, power Metal Oxide Semiconductor Field Effect Transistors (“MOSFET”), bipolar junction transistors (“BJTs”), Insulated Gate Bipolar Transistors (“IGBT”), Junction Barrier Schottky diodes, Gate Turn-Off Transistors (“GTO”), MOS-controlled thyristors and various other devices. These power semiconductor devices may be fabricated from silicon carbide (“SiC”).

### SUMMARY

Aspects and advantages of embodiments of the present disclosure will be set forth in part in the following description, or may be learned from the description, or may be learned through practice of the embodiments.

In an aspect, the present disclosure provides an example power semiconductor device. In some implementations, the example power semiconductor device includes a silicon carbide semiconductor structure. In some implementations, the example power semiconductor device includes at least one heterodoped layer in the silicon carbide semiconductor structure. In some implementations, the heterodoped layer includes a first layer having a first dopant concentration of a first conductivity type in a range of about 1×10¹⁷/cm³ to about 2×10²¹/cm³. The heterodoped layer includes a second layer having a second dopant concentration of the first conductivity type that is less than the first dopant concentration of the first layer. In some implementations, the semiconductor structure includes a drift region. The drift region has a third dopant concentration of the first conductivity type. The third dopant concentration is less than the first dopant concentration.

In an aspect, the present disclosure provides an example power semiconductor device. In some implementations, the example power semiconductor device includes a silicon carbide semiconductor structure. In some implementations, the example power semiconductor device includes at least one heterodoped layer in the silicon carbide semiconductor structure. In some implementations, the heterodoped layer includes a first layer having a first dopant concentration of a first conductivity type in a range of about 1×10¹⁷/cm³ to about 2×10²¹/cm³. The first layer has a first thickness in a range of about 10 nanometers to about 200 nanometers.

In an aspect, the present disclosure provides a semiconductor device. In some implementations, the example semiconductor device includes a silicon carbide semiconductor structure. The example semiconductor device includes a heterodoped lattice structure in the silicon carbide semiconductor structure. The heterodoped lattice structure includes at least two first layers having a first dopant concentration of a first conductivity type in a range of about 1×10¹⁷/cm³ to about 3×10¹⁹/cm³, wherein each first layer has a thickness in a range of about 10 nanometers to about 200 nanometers. The heterodoped lattice structure includes at least two second layers having a second dopant concentration of a first conductivity type that is less than the first dopant concentration of the plurality of first layers. The at least two first layers and the at least two second layers are arranged in alternating manner through a thickness of the silicon carbide semiconductor structure.

In an aspect, the present disclosure provides an example silicon carbide semiconductor device. In some implementations, the example silicon carbide semiconductor device includes a silicon carbide epitaxial semiconductor structure. In some implementations, the example silicon carbide semiconductor device includes a drift region in the epitaxial semiconductor structure. In some implementations, the example silicon carbide semiconductor device includes a heterodoped layer in the epitaxial semiconductor structure. The heterodoped layer includes a first layer having a first dopant concentration of a first conductivity type in a range of about 1×10¹⁷/cm³ to about 3×10¹⁹/cm³, wherein the first layer has a thickness in a range of about 10 nanometers to about 200 nanometers. In some implementations, the example silicon carbide semiconductor device includes at least two doped regions, each doped region comprising dopants of a second conductivity type.

In an aspect, the present disclosure provides an example power semiconductor device. In some implementations, the example power semiconductor device includes a silicon carbide semiconductor structure. In some implementations, the example power semiconductor device includes at least one heterodoped layer in the silicon carbide semiconductor structure. In some implementations, the heterodoped layer includes a first layer having a thickness of about 10 nm to about 200 nm, the first layer having a first dopant concentration of a first conductivity type. The heterodoped layer includes a second layer having a second dopant concentration of the first conductivity type. In some implementations, the first dopant concentration is at least 30 times greater than the second dopant concentration.

In an aspect, the present disclosure provides an example power semiconductor device. In some implementations, the example power semiconductor device includes a silicon carbide semiconductor structure. In some implementations, the example power semiconductor device includes a drift region in the silicon carbide semiconductor structure. In some implementations, the example power semiconductor device includes an active structure in the silicon carbide semiconductor structure. In some implementations, the example power semiconductor device includes a heterodoped layer in the silicon carbide semiconductor structure. The heterodoped layer includes a first layer having a first dopant concentration of a first conductivity type. The heterodoped layer includes a second layer having a second dopant concentration of the first conductivity type. The drift region has a third dopant concentration of the first conductivity type. The first dopant concentration and the second dopant concentration are different from the third dopant concentration.

In an aspect, the present disclosure provides an example power semiconductor device. In some implementations, the example power semiconductor device includes a silicon carbide semiconductor structure. In some implementations, the example power semiconductor device includes a drift region in the silicon carbide semiconductor structure. In some implementations, the example power semiconductor device includes an active structure in the silicon carbide semiconductor structure. In some implementations, the example power semiconductor device includes a first layer having a compensating component in the silicon carbide semiconductor structure, a concentration of the compensating component being in a range of about 1×10¹⁷/cm³ to about 2×10²¹/cm³. In some implementations, the compensating component includes one or more of germanium, phosphorus, tin, or arsenic.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1A depicts a cross-sectional view of an example MOSFET trench gate semiconductor device;

FIG. 1B depicts a cross-sectional view of an example MOSFET semiconductor device;

FIG. 1C depicts a cross-sectional view of an example Schottky diode semiconductor device;

FIGS. 2A, 2B, 2C, 2D, 2E, 2F, 2G, 2H, 2I, 2J, and 2K depict cross-sectional views of example semiconductor devices having a heterodoped layer according to example embodiments of the present disclosure;

FIGS. 3A, 3B, 3C, 3D, 3E, 3F, 3G, and 3H depict cross-sectional views of example semiconductor devices having a plurality of heterodoped layers according to example embodiments of the present disclosure;

FIGS. 4A and 4B depict cross-sectional views of example semiconductor devices having a heterodoped layer according to example embodiments of the present disclosure;

FIGS. 5A, 5B, 5C, 5D, 5E, and 5F depict cross-sectional views of an example semiconductor device having a heterodoped lattice structure according to examples of the present disclosure;

FIGS. 6A, 6B, 6C, 6D, and 6E depict cross-sectional views of an example semiconductor device according to example embodiments of the present disclosure;

FIG. 7 depicts a plot of electric field in a semiconductor structure of a semiconductor device having a plurality of heterodoped layers according to example embodiments of the present disclosure;

FIG. 8 depicts body diode snappiness improvement that may be accomplished using one or more heterodoped layers in a semiconductor structure according to example embodiments of the present disclosure;

FIGS. 9A and 9B depict example current distribution of an example semiconductor device according to example embodiments of the present disclosure; and

FIG. 10 depicts an example fabrication process of an example MOSFET device having a heterodoped lattice structure according to examples of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

High power semiconductor devices, including lateral and vertical power transistor structures, such as trench and planar MOSFETs, IGBTs, JFETs, FINFETs and BJTs and diode structures, such as JBS, PiN and Schottky diodes, are fabricated from silicon carbide Aspects of the present disclosure are discussed with reference to certain silicon carbide-based devices and structures therein. Those of ordinary skill in the art, using the disclosures provided herein, will understand that the silicon carbide-based structures and devices according to example embodiments of the present disclosure may be used with other devices and with silicon carbide materials incorporating other dopants and/or forming silicon carbide-based alloys, e.g. Si—Ge—C.

In general, to reduce the resistivity of the silicon carbide crystals, higher levels of dopants can be incorporated into the crystal. However, by introducing high levels of the dopants in the SiC crystal, undesirable defects can result in the crystal. So, there is a need for structures to provide appropriate or increased levels of dopants that result in improved performance in SiC devices.

Dopants can be of a first conductivity type (e.g., n-type). n-type dopants include nitrogen, phosphorus and/or arsenic. Dopants can be of a second conductivity type (e.g., p-type). P-type dopants can include boron and/or aluminum. Other dopants or alloy components or other components, such as compensating components, can include germanium, tin, arsenic, and/or phosphorus.

A silicon carbide power semiconductor device may comprise a silicon carbide substrate comprising a first conductivity type (e.g., an n-type substrate), on which an epitaxial structure (e.g., silicon carbide epitaxial structure) having the first conductivity type (e.g., n-type) is formed. A portion of this epitaxial structure (which may include one or more separate layers) may function as a drift region of the power semiconductor device. The device typically includes an “active structure,” which may include a junction such as a p-n junction or a channel region. The power semiconductor devices may have a unit cell structure in which the power semiconductor device includes a plurality of individual “unit cell” devices that are electrically connected in parallel and that together function as a single power semiconductor device. Herein, the term “semiconductor structure” refers to a structure that includes one or more semiconductor layers, such as semiconductor substrates and/or semiconductor epitaxial layers.

Power semiconductor devices can have a lateral structure or a vertical structure. In a device having a lateral structure, the terminals of the device (e.g., the drain, gate and source terminals for a power MOSFET device) are on the same major surface (e.g., top surface or bottom surface) of a semiconductor structure. In contrast, in a power semiconductor device having a vertical structure, at least one terminal is provided on each major surface of the semiconductor structure. For instance, in a vertical MOSFET device, the source may be on the top surface of the semiconductor structure and the drain may be on the bottom surface of the semiconductor structure.

Vertical power semiconductor devices, including a MOSFET transistor or an IGBT transistor, can have a gate contact design in which the gate contact of the transistor is formed on top of the semiconductor structure. Alternatively, the power semiconductor devices may have the gate contact in a gate trench within the semiconductor structure. Power semiconductor devices having trench gate contacts are typically referred to as trench gate devices (e.g., trench gate MOSFETs or trench gate IGBTs). With the standard gate contact design, the channel region of each unit cell transistor is horizontally disposed underneath the gate contact. In contrast, in the trench gate design, the channel is vertically disposed.

Power semiconductor devices may have a drift region in the epitaxial semiconductor structure with a uniform or nearly uniform dopant concentration across a thickness of the drift region. The thickness of the drift region refers to the dimension of the drift region between one or more active structures (e.g., doped regions at an upper surface of the semiconductor structure) and the substrate. For instance, the drift region may have a uniform or nearly uniform dopant concentration of dopants of a first conductivity type (such that the drift region is an n-type region). The dopant concentration may be, for instance, in a range of about 5×10¹⁵ to about 5×10¹⁶/cm³. The drift region may be “n-type.”.

Semiconductor devices used for power switching applications may need to provide current control through a diode. In some examples, in the case of a MOSFET, this may be achieved with a body diode of the semiconductor device between the source and the drain. In some examples, in the case of a Schottky diode, the diode functionality is provided with the Schottky diode itself. However, the diode may not be optimized for switching. In particular, the body diode of a MOSFET or a Schottky diode may suffer from a high degree of snappiness, which may increase switching times and switching losses. The snappiness of a diode characterizes the reverse recovery thereof. The snappiness provides a measure of the efficiency of the diode from changing from a conducting state to a non-conducting state during a change in voltage and/or current. A diode with reduced snappiness will be more efficient for use in power switching applications.

Aspects of the present disclosure are directed to including one or more heterodoped layers in semiconductor structure (e.g., in the epitaxial semiconductor structure) of a semiconductor device. The heterodoped layer may be a multilayer heterodoped layer comprising a first layer and a second layer. The heterodoped layer comprises a first layer having a high dopant concentration of dopants of a first conductivity type (e.g., n-type dopants, such as nitrogen dopants). The first layer may be an “n++ region.” For instance, a first dopant concentration of dopants of the first conductivity type in the first layer may be in the range of about 1×10¹⁷/cm³ to about 2×10²¹/cm³, such as in the range of 1×10¹⁷/cm³ to about 1×10²⁰/cm³, such as in the range of 1×10¹⁷/cm³ to about 3×10¹⁹/cm³, such as in a range of about 1×10¹⁷/cm³ to about 5×10¹⁸/cm³, such as in a range of about 5×10¹⁷/cm³ to about 5×10¹⁸/cm³. The heterodoped layer includes a second layer. The second layer has a second dopant concentration of dopants of the first conductivity type that is significantly less than the first dopant concentration. The second layer may be an “n-” region. In some examples, the second dopant concentration may be, for instance, a dopant concentration in a range of about 1×10¹³/cm³ to about 5×10¹⁵/cm³, such as in a range of about 5×10¹³/cm³ to about 5×10¹⁵/cm³, such as in a range of about 1×10¹⁴/cm³ to about 5×10¹⁵/cm³, such as in a range of about 5×10¹⁴/cm³ to about 5×10¹⁵/cm³. In some embodiments, the second layer may be undoped. As used herein, a layer is undoped when there are no dopants or where the layer is just unintentionally doped. Examples of unintentionally doped layers include layers that are doped with remaining dopants that are in the processing chamber after dopant source(s) have been turned off or layers with only dopants diffusing from adjacent or other layers. An undoped layer or region includes layers or regions having a doping level below that which can be detected, such as below about 1×10¹⁴, such as below about 1×10¹⁵.

In some examples, the first dopant concentration may be at least twenty times the second dopant concentration, such as in a range of about 20 times to about 60 times the second dopant concentration, such as about 30 times to about 60 times, such as about 30 times to about 40 times the second dopant concentration, such as about 30 times to about 35 times the second dopant concentration. In other embodiments, the first concentration can be greater than 60 times the second doping concentration, greater than 100 times the second doping concentration, greater than 150 times the second doping concentration; greater than 200 times the second doping concentration; greater than 300 times the second doping concentration; or greater than 400 times the second doping concentration. In some embodiments, the first dopant concentration can be multiple orders of magnitude greater than the second doping concentration, such as greater than 1000 times or 103, greater than 10 thousand times or 104 or greater than 100,000 or 105.

In some embodiments the first layer comprises a delta doped layer that is doped at such a high level that it is maintained relatively thin because the high level of doping can lead to a detrimental effect on quality and/or increased level of defects (or polytypes) in the crystal if the layer were grown thicker. In some embodiments, the delta doped layer is grown such that the dopant reactants are turned on in the growth chamber while one of the crystal reactants is momentarily shut down to increase the level of doping in the thin layer. In some embodiments, a layer can be distinct, indistinct, continuous or discontinuous. A layer can be made as thin as possible by reducing the crystal growth rate when growing the heterodoped layer or at least the highly doped thinner layer.

Depending on the embodiment, the heterodoped layer can comprise a first layer with higher doping (e.g., about 1×10¹⁷/cm³ to about 2×10²¹/cm³, such as in the range of 1×10¹⁷/cm³ to about 1×10²⁰/cm³, such as in the range of about 1×10¹⁷/cm³ to about 3×10¹⁹/cm³, such as in a range of about 1×10¹⁷/cm³ to about 5×10¹⁸/cm³, such as in a range of about 5×10¹⁷/cm³ to about 5×10¹⁸/cm³) and a second layer with lower doping (e.g., 1×10¹³/cm³ to about 5×10¹⁵/cm³ or less, such as about 5×10¹³/cm³ to about 5×10¹⁵/cm³, such as in a range of about 1×10¹⁴/cm³ to about 5×10¹⁵/cm³, such as in a range of about 5×10¹⁴/cm³ to about 5×10¹⁵/cm³ or undoped) where a total electrical charge for the heterodoped layer can be adjusted to be equivalent to a semiconductor structure with an intermediate uniform doping level (e.g., about 1×10¹⁶/cm³ to about 1×10¹⁷/cm³) that is lower than the first doping concentration but with improved snappiness. Depending on the embodiment, using a heterodoped layer(s) with a relatively thin higher doped layer adjacent a thicker lower doped layer can achieve an electric charge equivalent to a SiC structure with a uniform intermediate doping (e.g., about 1×10¹⁶/cm³ to about 5×10¹⁶/cm³). As a result, the thicker lower doped layer can provide a longer mean free path for minority carriers so that the snappiness of the device is improved. Moreover, depending on the embodiment, the heterodoped layer can serve as a current spreading layer along the first highly doped layer when the majority carriers flow into the highly doped first layer and meet higher resistance in the second lower doped layer. The heterodoped layer may also provide strain compensation and defect termination. These effects may be increased by using multiple and/or repeating heterodoped layers.

Depending on the embodiment, the heterodoped layer can comprise multiple heterodoped layers where multiple heterodoped layers repeat in a lattice structure and/or multiple heterodoped layers are separated from each other. Heterodoped layers may include intervening layers. Within a heterodoped layer, the doping may be graded in an increasing, decreasing, uniform and/or stepwise graded fashion or other variable distribution. Between heterodoped layers, layers of the same or different thicknesses (increasing and/or decreasing thickness) can be used, and doping levels of the same or different levels, (increasing, decreasing uniform or stepwise grading is possible, depending on the desired performance).

In some embodiments, the first layer may be very thin relative to the semiconductor structure and/or relative to the second layer of the heterodoped layer. For instance, the first layer may have a first thickness in a range of about 10 nanometers (nm) to about 200 nm, such as about 30 nm to about 180 nm, such as about 40 nm to about 150 nm, such as about 50 to about 100 nm, such as about 60 nm to about 100 nm. The second layer may have a second thickness that is greater than the first thickness, such as at least twice the first thickness, such as at least five times the first thickness, such as at least 10 times the first thickness, such as in a range of about 20 nanometers or 0.02 microns to about 4 microns, such as about 0.04 microns to about 3 microns, from about 0.05 microns to about 2 microns, from about 0.1 microns to about 1.5 micron, from about 0.04 micron to about than 0.75 microns.

In some examples, the second layer (e.g., n-region) of the heterodoped layer may have a graded distribution or other varying distribution of dopants across a thickness of the second layer. In some examples, the distribution of dopants across the thickness of the second layer may be such that a minimum or lower dopant concentration is at an area adjacent to the first layer of high dopant concentration. This may provide a sharp interface or contrast in dopant concentration at an interface between the first layer (e.g., n++) and the second layer (e.g., n−), which may lead to enhanced current spreading effects of the first layer in the semiconductor structure. In some examples, the first layer may have a graded distribution or other varying distribution across a thickness of the first layer. In some examples, the distribution of dopants across the first layer is such that a maximum or higher dopant concentration is at an area adjacent to the second layer of lower dopant concentration. As such, this may provide a sharp interface or contrast between the first layer (e.g., n++) and the second layer (e.g., n−) which may lead to improved current spreading or other effects.

The heterodoped layer(s) may be at any location in the semiconductor structure. For instance, in some examples, the heterodoped layer(s) may be in the drift region. In some examples, the heterodoped layer(s) may be in an active structure (e.g., near implanted regions located at or near a surface of the semiconductor structure) of the semiconductor structure. In some examples, the heterodoped layer(s) may be at or near the substrate. In some examples, the heterodoped layer(s) may be at two or more locations selected from the drift region, active structure, and/or near the substrate. The heterodoped layer(s) can also be positioned in the active region and/or other regions where there is current crowding, points of increased resistance and/or current pinch or carrier depletion points/regions, (e.g., narrowest point or region between p-wells, area between JFET region and drift region, etc.).

The heterodoped layer(s) may be included adjacent other doped layers without deviating from the scope of the present disclosure. For instance, in some examples, a heterodoped layer may be adjacent a layer of low dopant concentration (e.g., n− layer) such that a single first layer of high dopant concentration (e.g., n++ region) is between two second layers of low dopant concentration (e.g., n− regions). In some examples, a heterodoped layer may be adjacent a layer of high dopant concentration such that a single second layer of low dopant concentration (e.g., n− region) that is between two first layers of high dopant concentration (e.g., n++ regions). Other arrangements of heterodoped layers with other doped layers may be used without deviating from the scope of the present disclosure.

A heterodoped layer in any embodiment can comprise multiple sets of heterodoped layers where each set comprises at least a first and second layer as described herein with the same and/or different characteristics, such as doping levels and/or thicknesses. In some embodiments, a heterodoped layer can comprise additional or intervening layers. Also, depending on the embodiment, a heterodoped layer can be located in different or multiple locations within the device. A layer can be discontinuous, the doping can be stepwise or continuously graded in the same or different directions. The first and second layers can be symmetric and/or asymmetric.

In some examples, the heterodoped layer may be or may include a compensating component. For instance, a first layer of the heterodoped layer may be or may include a compensating component. The compensating component may be, for instance, one or more of germanium, tin, arsenic, or phosphorus. The compensating component may be provided as dopants to the silicon carbide. However, in some embodiments, the compensating component may be alloyed with the silicon carbide (e.g., silicon carbide alloyed with germanium). The compensating component, in some embodiments, may provide for bandgap engineering of the semiconductor structure. For instance, current spreading, snappiness effects, strain compensation and defect termination may be improved by modifying the bandgap of the semiconductor structure in the first layer of the heterodoped layer.

In some aspects, the semiconductor device may include a heterodoped lattice structure including a plurality of heterodoped layers in the semiconductor structure, such as two or more heterodoped layers, such as five or more heterodoped layers, such as ten or more heterodoped layers. Each heterodoped layer may include a first layer of high dopant concentration (e.g. n++) and a second layer of lower dopant concentration (e.g., n−). Intervening or additional layers are possible within a heterodoped layer or between heterodoped layers. The first layer may be relatively thin compared to the second layer. The first layers and the second layers of the heterodoped lattice structure may be arranged in an alternating manner through a thickness of the semiconductor structure (e.g., the epitaxial semiconductor structure), such as through a thickness of the drift region to provide the heterodoped lattice structure.

Aspects of the present disclosure may provide a number of technical effects and benefits. For instance, the incorporation of the heterodoped layer(s) into the semiconductor structure may provide for a longer mean free path for minority carriers in the epitaxial structure (e.g., in the drift region). The first layer of high dopant concentration (e.g., n++ layer) may act to spread a current conducting through the epitaxial structure (e.g., in the drift region) to provide a wide path for the current in the epitaxial structure. This may lead to improved diode snappiness of the semiconductor device, which may further provide enhanced switching performance in power switching applications.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to silicon carbide-based transistor and diode devices for purposes of illustration and discussion. Those of ordinary skill in the art, using the disclosures provided herein, will appreciate that certain aspects of the present disclosure may be applicable to other transistor or diode devices without deviating from the scope of the present disclosure.

In the drawings and specification, there have been disclosed typical embodiments and, although specific terms are employed, they are used in a generic and descriptive sense only and not for purposes of limitation of the scope set forth in the following claims.

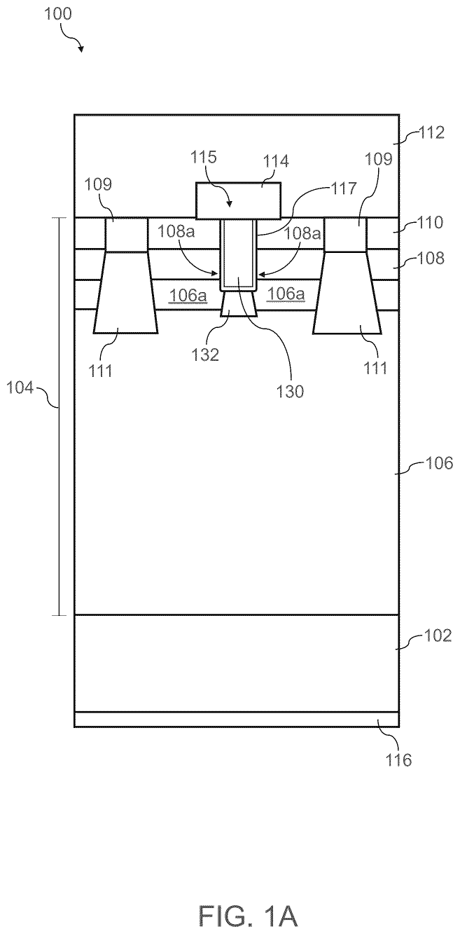

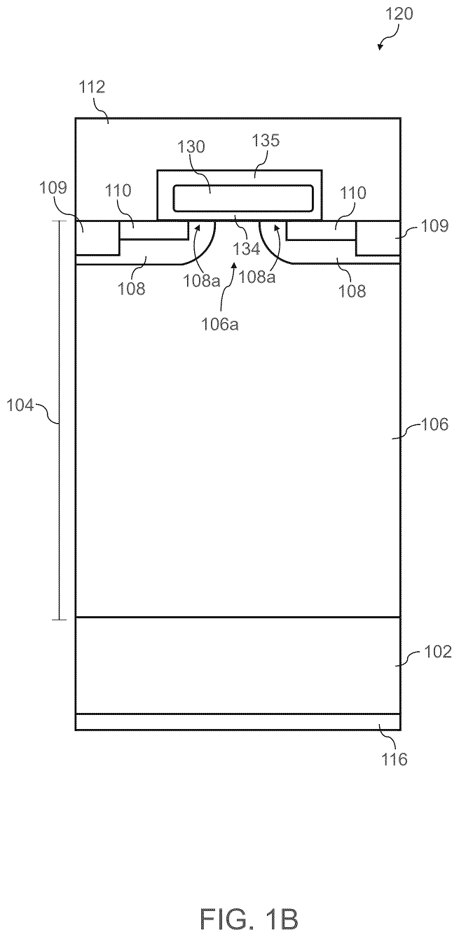

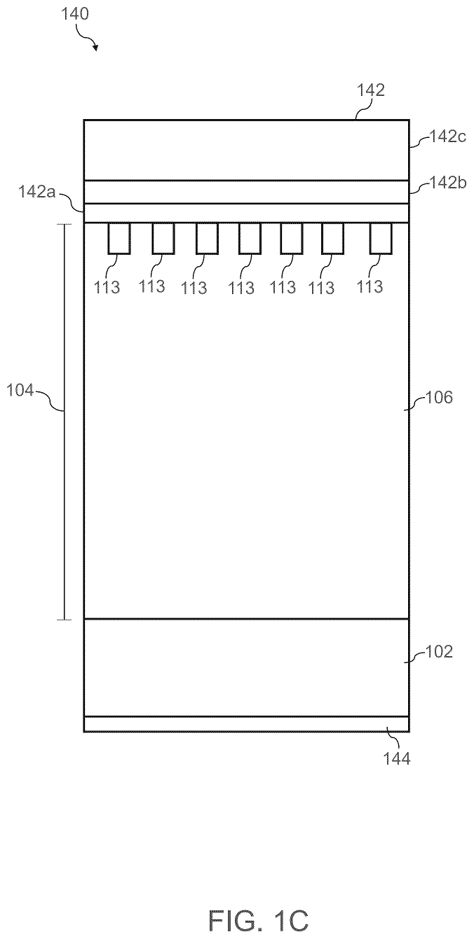

active structure active structure FIG. 1A is a cross-sectional view of a unit cell of an example power silicon carbide-based semiconductor device 100. The power semiconductor device 100 of FIG. 1A is a silicon carbide-based trench gate MOSFET. FIG. 1A is intended to represent structures for identification and description and is not intended to represent the structures to physical scale.

The power semiconductor device 100 includes a silicon carbide substrate 102. The power semiconductor device 100 includes a silicon carbide-based semiconductor structure 104 (e.g., epitaxial semiconductor structure) on the silicon carbide substrate 102. The substrate 102 may include, for example, a single crystal 4H silicon carbide semiconductor substrate. The substrate 102 may be heavily doped with n-type dopants (e.g., an n+ silicon carbide substrate). The dopants may comprise, for example, nitrogen or phosphorus or other suitable dopants. The substrate 102 may be any appropriate thickness (e.g., in a range of about 50 microns to about 500 microns, such as about 100 microns to about 360 microns, such as about 200 microns to about 300 microns, but thinner or thicker substrates are possible). Other substrates may be used without deviating from the scope of the present disclosure. The silicon carbide-based semiconductor structure 104 may be epitaxially formed on the substrate 102, for example by chemical vapor deposition (CVD) or other suitable growth techniques. Dopant implantation processes may be used to form doped regions in the semiconductor structure 104 (e.g., n-type regions, p-type regions) as described below.

The silicon carbide-based semiconductor structure 104 may include a doped (e.g., n-doped) silicon carbide drift region 106 on the substrate 102. The silicon carbide drift region 106 may be formed on the substrate 102 by epitaxial growth, for example, by CVD. The drift region 106 of FIG. 1A may have a uniform or nearly uniform dopant concentration across a thickness of the drift region 106. For instance, the drift region 106 may have a uniform or nearly uniform dopant concentration of dopants of a first conductivity type (such that the drift region is an n-type region). However, in other embodiments, the drift region 106 may have a non-uniform dopant concentration, such as a gradient dopant concentration that increases and/or decreases through a thickness of the drift region 106. The upper portion of the drift region may comprise a more highly doped JFET region 106a, as will be discussed in further detail below.

The dopant concentration of the drift region 106 may be, for instance, in a range of about 1×10¹⁴/cm³ to about 1×10¹⁷/cm³ such as about 1×10¹⁵/cm³ to about 2×10¹⁶/cm³, such as about 5×10¹⁵/cm³ to about 1×10₁₆. The dopants may be, for example, nitrogen dopants or phosphorous dopants or any other suitable dopants. The drift region 106 may have a thickness in a range of about 1 micron to about 100 microns, such as about 3 microns to about 100 microns, such as about 6 microns to about 100 microns, such as about 3 microns to about 50 microns, such as about 3 microns to about 20 microns, such as about 4 microns to about 15 microns, such as about 4 microns to about 10 microns.

A silicon carbide p-type well region 108 may be on the drift region 106. The p-type well region 108 may provide p-wells for the power semiconductor device 100. The p-type well region 108 may be formed, for instance, by epitaxial growth followed by implantation of p-type dopants. The p-type well regions 108 may be moderately doped with p-type dopants (e.g., aluminum, boron, gallium, indium) at concentrations in a range of about 1×10¹⁶/cm³ to about 1×10¹⁸/cm³, such about 5×10¹⁶/cm³ to about 2×10¹⁷/cm³, such as about 5×10¹⁶/cm³ to about 1×10¹⁷/cm³. In some embodiments, the concentration of dopants in the p-type well regions 108 may be higher than the concentration of dopants in the drift region 106.

An n-type source region 110 may be on the well region 108. The source region 110 may be heavily doped with an n-type doping material (n+) at a dopant concentration, for instance, in a range of about 1×10¹⁸/cm³ to about 5×10²¹/cm³, such as about 1×10¹⁹/cm³ to about 1×10²¹/cm³, such as about 5×10¹⁹/cm³ to about 5×10²⁰/cm³. The heavily doped n-type source region 110 may be formed by epitaxial growth followed by ion implantation of n-type dopants (e.g., nitrogen, phosphorus). In some embodiments, however, the n-type source region 110 may be formed by epitaxial growth.

The silicon carbide-based semiconductor structure 104 may include one or more p-type contact regions 109 (p+ regions). The p-type contact regions 109 may be more heavily doped with p-type dopants than the p-type well regions 108. The p-type contact regions 109 may be formed, for instance, by implantation of p-type dopants into the semiconductor structure 104. In some embodiments, however, the p-type contact regions 109 may be formed by epitaxial growth. The p-type contact regions 109 may be heavily doped with a p-type doping material at concentrations in a range of about 1×10¹⁹/cm³ to 1×10²¹ cm³, such as about 5×10¹⁹/cm³ to 5×10²⁰ cm³, such as about 5×10¹⁹/cm³ to 1×10²⁰ cm³. Each p-type contact region 109 may be laterally adjacent one or more source regions 110 and may extend between a top surface of the semiconductor structure 104 and a respective one of a plurality of support shield regions 111.

The silicon carbide-based semiconductor structure 104 may include p-type support shield regions 111. The p-type support shield region(s) 111 may be formed, for instance, by epitaxial growth followed by implantation of p-type dopants. The support shield regions 111 may be heavily doped with a p-type doping material (p+) at concentrations in a range of about 5×10¹⁶/cm³ to about 1×10²¹/cm³, such as about 1×10¹⁷/cm³ to about 5×10²⁰/cm³, such as about 5×10¹⁷/cm³ to about 1×10²⁰/cm³. In some embodiments, the concentration of dopants in the p-type shield regions(s) 111 may be at least 5 times higher than a concentration of dopants in the drift layer 106, or at least about 10 times higher. The support shield region(s) 111 may be provided between gate trenches (e.g., a gate trench 115) in the semiconductor device 100 to block electric fields during reverse blocking operation of the trench gate MOSFET 100.

The semiconductor device includes a gate trench 115 in the silicon carbide-based semiconductor structure 104. The gate trench 115 extends through the source region 110, the well region 108 and onto the drift region 106. A gate dielectric layer 117 may be along a bottom surface and sidewalls of the gate trench 115. The gate dielectric layer 117 may be, for example, an oxide layer, and may include one or more layers. In some examples, the gate dielectric layer 117 includes one or more of SiO₂, SiN, Al₂O₃, MgOₓ, MgNₓ, ZnO, SiNₓ, SiOₓ, HfOₓ or other suitable dielectric layer. The gate dielectric layer 117 may insulate a gate structure 130 from the semiconductor structure 104.

A gate structure 130 may be in the gate trench 115. The gate structure 130 may comprise a metal and/or doped polysilicon on the gate dielectric layer 117 (e.g., gate oxide). In some examples, the gate structure 130 may be part of a continuous gate pattern including one or more gate buses, gate pads, etc. The gate structure 130, in some embodiments, may partially fill the gate trench 115 (so that the upper surface of the gate structure 130 is below an upper surface of the gate trench 115), may fill the gate trench 115, or may fill the gate trench, or may fill the gate trench and extend onto portions of the semiconductor structure 104 that are on either side of the gate trench 115.

In some examples, the semiconductor structure 104 may include a p-type trench shield region 132 in the semiconductor structure 104. The trench shield region 132 may be heavily doped with a p-type doping material (p+) at concentrations in a range of about 1×10¹⁸/cm³ to about 1×10²¹/cm³, such as about 5×10¹⁸/cm³ to about 5×10²⁰/cm³, such as about 1×10¹⁹/cm³ to about 1×10²⁰/cm³. The trench shield region 132 may be beneath the gate trench 115 and may act to reduce electric field levels formed in the gate dielectric 117 during operation of the trench gate MOSFET device 100. In some embodiments, the trench shield region 132 may extend to a same depth as the support shield region(s) 111 in the semiconductor structure 104. In some embodiments, the trench shield region may extend to a different depth (e.g., deeper or not as deep), in the semiconductor structure 104. In some embodiments, the semiconductor device 100 does not include a trench shield region 132 or support shield region(s) 111. In some embodiments, the semiconductor device 100 includes a trench shield region 132 but does not include support shield region(s) 111. In some embodiments, the semiconductor device 100 includes support shield region(s) 111 but does not include a trench shield region 132.

A source electrode 112 may be on the n-type source regions 110 and p-type contact regions 109. The source electrode 112 may provide an ohmic contact with the semiconductor structure 104. The source electrode 112 may include, for example, one or more metals such as nickel, titanium, tungsten or aluminum, or alloys or layered stacks of these or other suitable materials. In some embodiments, the source electrode 112 may include a separate ohmic contact layer (not shown), for instance, made of nickel silicide that may be formed by depositing a nickel layer which may be annealed into the silicon carbide semiconductor structure 104 to form the nickel silicide ohmic contact.

An insulating portion 114 may electrically insulate the source electrode 112 from the gate structure 130. The insulating portion 114 can be an intermetal dielectric and can include any suitable dielectric material.

A drain electrode 116 may be on the lower surface of the substrate 102. The drain electrode 116 may include, for example, similar materials to the source electrode 112, as this forms an ohmic contact to the silicon carbide substrate 102. The drain electrode 116 may include, for example, metals such as nickel, titanium, tungsten or aluminum, or alloys or layered stacks of these or other suitable materials.

The semiconductor structure 104 may include a channel region 108a and a JFET region 106a. The channel region 108a may be the portion of the p-well region 108 that is adjacent to the gate trench 115. The JFET region 106a may be between the trench shield region 132 and the support shield region(s) 111. The JFET region 106a may be a part of the drift region 106. In some embodiments, the JFET region 106a may have a dopant concentration of dopants of the first conductivity type (e.g., n-type dopants) that may be greater than a dopant concentration of the remainder of the drift region 106. The JFET region 106a may have a portion that begins above the bottom of the gate trench 115 and extends to a depth in the semiconductor structure 104. The JFET region 106a may extend to a depth that is above, co-planar with, or below the depth of the support shield region(s) 111 and/or trench shield region 132.

When a sufficient bias voltage is applied to the gate structure 130 in the gate trench 115, electrons will flow from the source electrode 190 to the drain electrode 192 through the channel region 108a and JFET region 106a into the drift layer 106. More specifically, the electrons flow from the source electrode 112, through the channel 108a and then into the JFET region 106a on its path to the drain electrode 116.

While the semiconductor device 100 is illustrated and described as an n-type device, aspects of the present disclosure are similarly applicable to p-type devices, where the n-type layers described above are p-type layers and the p-type layers described above are n-type layers.

FIG. 1B is a cross-sectional view of an example unit cell of an example power semiconductor device 120. The power semiconductor device 120 of FIG. 1B is a silicon carbide-based MOSFET having a planar gate structure. FIG. 1B is intended to represent structures for identification and description and is not intended to represent the structures to physical scale.

The power semiconductor device 100 includes a silicon carbide substrate 102. The power semiconductor device 100 includes a silicon carbide-based semiconductor structure 104 (e.g., epitaxial semiconductor structure) on the silicon carbide substrate 102. The substrate 102 may include, for example, a single crystal 4H silicon carbide semiconductor substrate. The substrate 102 may be heavily-doped with n-type dopants (e.g., an n+ silicon carbide substrate). The dopants may comprise, for example, nitrogen or phosphorus or other suitable dopants. The substrate 102 may be any appropriate thickness (e.g., in a range of about 50 microns-to about 500 microns, such as about 100 microns to about 360 microns, such as about 200 microns to about 300 microns, but thinner or thicker substrates are possible). Other substrates may be used without deviating from the scope of the present disclosure. The silicon carbide-based semiconductor structure 104 may be epitaxially formed on the substrate 102, for example by chemical vapor deposition (CVD) or other suitable growth techniques. Dopant implantation processes may be used to form doped regions in the semiconductor structure 104 (e.g., n-type regions, p-type regions) as described below.

The silicon carbide-based semiconductor structure 104 may include a doped (e.g., n-doped) silicon carbide drift region 106 on the substrate 102. The silicon carbide drift region 106 may be formed on the substrate 102 by epitaxial growth, for example, by CVD. The drift region 106 of FIG. 1B may have a uniform or nearly uniform dopant concentration across a thickness of the drift region 106. For instance, the drift region 106 may have a uniform or nearly uniform dopant concentration of dopants of a first conductivity type (such that the drift region is an n-type region). However, in other embodiments, the drift region 106 may have a non-uniform dopant concentration, such as a graded dopant concentration that increases and/or decreases through a thickness of the drift region 106. The upper portion of the drift region may comprise a more highly doped JFET region 106a, as will be discussed in further detail below.

The dopant concentration of the drift region 106 may be, for instance, in a range of about 1×10¹⁴/cm³ to about 1×10¹⁷/cm³ such as about 1×10¹⁵/cm³ to about 2×10¹⁶/cm³, such as about 5×10¹⁵/cm³ to about 1×10¹⁶. The dopants may be, for example, nitrogen dopants or phosphorous dopants or other suitable dopants. The drift region 106 may have a thickness in a range of about 1 micron to about 100 microns, such as about 3 microns to about 100 microns, such as about 6 microns to about 100 microns, such as about 3 microns to about 50 microns, such as about 3 microns to about 20 microns, such as about 4 microns to about 15 microns, such as about 4 microns to about 10 microns.

A p-type silicon carbide well region 108 may be on the drift region 106. The p-type well region 108 may be formed, for instance, by epitaxial growth followed by implantation of p-type dopants. The p-type well regions 108 may be moderately doped with p-type dopants (e.g., aluminum, boron, gallium, indium) at concentrations in a range of about 1×10¹⁶/cm³ to about 1×10¹⁸/cm³, such about 5×10¹⁶/cm³ to about 2×10¹⁷/cm³, such as about 5×10¹⁶/cm³ to about 1×10¹⁷/cm³. In some embodiments, the concentration of dopants in the p-type well regions 108 may be higher than the concentration of dopants in the drift region 106.

The silicon carbide-based semiconductor structure 104 may include one or more p-type contact regions 109 (e.g., p+ regions). The p-type contact regions 109 may be more heavily doped with p-type dopants than the p-well regions 108. The p-type contact regions 109 may be formed, for instance, by implantation of p-type dopants into the semiconductor structure 104. However, in some embodiments, the p-type contact regions 109 may be formed by epitaxial growth. The p-type contact regions 109 may be heavily doped with a p-type doping material at concentrations in a range of about 1×10¹⁹/cm³ to 1×10²¹ cm³, such as about 5×10¹⁹/cm³ to 5×10²⁰ cm³, such as about 5×10¹⁹/cm³ to 1×10²⁰ cm³.

An n-type source region 110 may be on the p-well region 108. The source region 110 may be heavily doped with an n-type doping material (n+) at a dopant concentration, for instance, in a range of about 1×10¹⁸/cm³ to about 5×10²¹/cm³, such as about 1×10¹⁹/cm³ to about 1×10²¹/cm³, such as about 5×10¹⁹/cm³ to about 5×10²⁰/cm³. The heavily doped n-type source region 110 may be formed by ion implantation of n-type dopants into the epitaxially formed semiconductor structure 104. However, in some embodiments, the source regions 110 may be formed by epitaxial growth.

A source electrode 112 may be on the n-type source regions 110 and the one or more p-type contact regions 109. The source electrode 112 may provide an ohmic contact with the semiconductor structure 104. The source electrode 112 may include, for example, metals such as nickel, titanium, tungsten or aluminum, or alloys or layered stacks of these or other suitable materials. In some embodiments, the source electrode 112 may include a separate ohmic contact layer (not shown), for instance, made of nickel silicide that may be formed by depositing a nickel layer which may be annealed into the silicon carbide semiconductor structure 104 to form the nickel silicide ohmic contact.

A drain electrode 116 may be on the lower surface of the substrate 102. The drain electrode 116 may include, for example, similar materials to the source electrode 112, as this forms an ohmic contact to the silicon carbide substrate 102. The drain electrode 116 may include, for example, metals such as nickel, titanium, tungsten or aluminum, or alloys or layered stacks of these or suitable materials.

A gate structure 130 may be proximate the semiconductor structure 104. A gate dielectric layer 134 may be between the gate structure 130 and the semiconductor structure 104. The gate dielectric layer 134 may insulate the gate structure 130 from the semiconductor structure 104. The gate dielectric layer 134 may be, for instance, an oxide layer. In some examples, the gate dielectric layer 134 includes a silicon dioxide layer or other suitable dielectric between the gate structure 130 and the semiconductor surface. In some embodiments, the gate dielectric layer 134 comprises one or more of SiN, Al₂O₃, MgOₓ, MgNₓ, ZnO, SiNₓ, SiOₓ, HfOₓ or other suitable dielectric layers. A separate intermetal dielectric 135 may be formed over the gate structure 130 to insulate the gate structure 130 from the source electrode 112.

In some embodiments, the gate structure 130 may comprise a metal and/or doped polysilicon. In some examples, the gate structure 130 may be part of a continuous gate pattern including one or more gate buses, gate pads, etc.

The upper portion of each p-type well region 108, which is underneath and overlapping the gate structure 130, may provide a channel region 108a for the MOSFET semiconductor device 120. The drift region 106 may also include a JFET region 106a between the well regions 108 and beneath the gate structure 130 and gate dielectric layer 134. In some embodiments, the JFET region 106a may have a dopant concentration of dopants of the first conductivity type (e.g., n-type dopants) that may be greater than a dopant concentration of the remainder of the drift region 106. Application of a bias voltage to the gate structure 130 may cause electrons to flow from the source electrode 112 to the drain electrode 116 through source region 110 and through the channel regions 108a to the JFET region 106a and through the drift region 106 to the drain electrode 116.

While the power semiconductor device 120 is an n-type device, aspects of the present disclosure are similarly applicable to p-type devices, and such a device simply replaces the n-type materials with p-type materials and p-type materials with n-type materials.

FIG. 1C is a cross-sectional view of an example unit cell of an example silicon carbide-based semiconductor device 140. The semiconductor device 140 of FIG. 1C is a silicon carbide-based Schottky diode. FIG. 1C is intended to represent structures for identification and description and is not intended to represent the structures to physical scale.

The power semiconductor device 100 includes a silicon carbide substrate 102. The power semiconductor device 100 includes a silicon carbide-based semiconductor structure 104 (e.g., epitaxial semiconductor structure) on the silicon carbide substrate 102. The substrate 102 may include, for example, a single crystal 4H silicon carbide semiconductor substrate. The substrate 102 may be heavily doped with n-type dopants (e.g., an n+ silicon carbide substrate). The dopants may comprise, for example, nitrogen or phosphorus or other suitable dopants. The substrate 102 may be any appropriate thickness (e.g., in a range of about 50 microns-to about 500 microns, such as about 100 microns to about 360 microns, such as about 200 microns to about 300 microns, but thinner or thicker substrates are possible). Other substrates may be used without deviating from the scope of the present disclosure. The silicon carbide-based semiconductor structure 104 may be epitaxially formed on the substrate 102, for example by chemical vapor deposition (CVD) or other suitable growth techniques. Dopant implantation processes may be used to form doped regions in the semiconductor structure 104 (e.g., p-type or n-type regions) as described below.

The silicon carbide-based semiconductor structure 104 may include a doped (e.g., n-doped) silicon carbide drift region 106 on the substrate 102. The silicon carbide drift region 106 may be formed on the substrate 102 by epitaxial growth, for example by chemical vapor deposition. The drift region 106 of FIG. 1C may have a uniform or nearly uniform dopant concentration across a thickness of the drift region 106. For instance, the drift region 106 may have a uniform or nearly uniform dopant concentration of dopants of a first conductivity type (such that the drift region is an n-type region). However, in other embodiments, the drift region 106 may have a non-uniform dopant concentration, such as a graded dopant concentration that increases and/or decreases through a thickness of the drift region 106.

The dopant concentration of the drift region 106 may be, for instance, in a range of about 1×10¹⁴/cm³ to about 1×10¹⁷/cm³ such as about 1×10¹⁵/cm³ to about 2×10¹⁶/cm³, such as about 5×10¹⁵/cm³ to about 1×10¹⁶. The dopants may be, for example, nitrogen dopants or phosphorous dopants or any other suitable dopants. The drift region 106 may have a thickness in a range of about 1 micron to about 100 microns, such as about 3 microns to about 100 microns, such as about 6 microns to about 100 microns, such as about 3 microns to about 50 microns, such as about 3 microns to about 20 microns, such as about 4 microns to about 15 microns, such as about 4 microns to about 10 microns.

The semiconductor device further includes Schottky junction barrier regions 113. The Schottky junction barrier regions 113 may be formed by implantation of p-type dopants into the drift region 106. The Schottky junction barrier regions 113 may have a dopant concentration of in a range of about 1×10¹⁷/cm³ to 1×10²¹/cm³, such as about 1×10¹⁸/cm³ to 5×10²⁰/cm³, such as about 5×10¹⁸/cm³ to 1×10²⁰/cm³. The Schottky junction barrier regions 113 may form an array and may have various shapes. For instance, each Schottky junction barrier region 113 may take the form of an elongated strip or may take the form of a circular or other shaped island.

The semiconductor device 140 includes a cathode electrode 144. The cathode electrode 144 may be on the substrate 102 and may form an ohmic contact with the substrate 102. The cathode electrode 144 may include, for example, metals such as nickel, titanium, tungsten or aluminum, or alloys or layered stacks of these or other suitable materials.

The semiconductor device 140 includes an anode electrode 142 (e.g., metal stack) on the drift region 106. The anode electrode 142 may be a single layer or multi-layer stack. In some embodiments, the anode electrode may include a Schottky layer 142a, a barrier layer 142b, and/or an anode electrode layer 142c.

The Schottky layer 142a may form a Schottky contact with the drift region 106. The Schottky layer 142a may form an ohmic contact or a low breakdown voltage Schottky contact with the Schottky junction barrier region(s) 108. The Schottky layer 142a may comprise aluminum, tantalum, and/or titanium. A thickness of the Schottky layer 142a will vary based on desired device characteristics and the metal used to form the Schottky layer 142a, but will generally be between about 100 angstroms and about 4500 angstroms. For instance, a Schottky layer 142a formed of tantalum may be between about 200 angstroms and 1200 angstroms; a Schottky layer 142a formed of titanium may be between about 500 angstroms and 2500 angstroms; and a Schottky layer 142a formed of aluminum may be between about 3500 angstroms and 4500 angstroms.

The barrier layer 142b may be formed of titanium tungsten alloy, titanium nickel alloy, tantalum, and/or any other suitable material, and may be between about 75 angstroms and 400 angstroms thick in some embodiments. The barrier layer 142b helps prevent diffusion between the metals used to form the Schottky layer 142a and the anode electrode layer 142c.

The anode electrode layer 142c may be relatively thick, formed from a metal, and may act as a bond pad for the anode of the Schottky diode 140. The anode electrode layer 142c may be formed from aluminum (Al), gold (Au), silver (Ag), and/or any other suitable material.

With the presence of the Schottky junction barrier regions 113, there may be at least two types of junctions in the upper portion of the semiconductor structure 104. The first is referred to as a Schottky junction and is any metal-semiconductor junction between the Schottky layer 142a and those portions of the top surface of the drift layer 106 that do not have a Schottky junction barrier region 113. In other words, the Schottky junction is a junction between the Schottky layer 142a and the portions of the top surface of the drift layer 106 that are between two adjacent Schottky junction barrier regions 113. The second junction is referred to as a junction barrier junction (JB junction) and is any p-n junction between a Schottky junction barrier region 113 (e.g. p-type) and the drift layer 106 (e.g., n-type).

As the Schottky diode 140 is forward-biased, the Schottky junctions turn on before the JB junctions turn on. At low forward voltages, current transport in the Schottky diode 140 is dominated by majority carriers (electrons) injected across the Schottky junction. As such, the Schottky diode 140 acts like a traditional Schottky diode. In this configuration, there is little or no minority carrier injection, and thus no minority charge. As a result the Schottky diode 140 is capable of fast switching speeds at normal operating voltages.

When the Schottky diode 140 is reverse-biased, depletion regions that form adjacent the JB junctions expand to block reverse current through the Schottky diode 140. As a result, the expanded depletion regions function to both protect the Schottky junction and limit reverse leakage current in the Schottky diode 140. With the Schottky junction barrier regions 113, the Schottky diode 140 behaves like a PIN diode.

While the power semiconductor device 140 is an n-type device, the present disclosure is similarly applicable to p-type devices, and such a device simply replaces the n-type materials with p-type materials and p-type materials with n-type materials.

The dopant concentration of any of the doped regions discussed herein may have any suitable distribution of dopants without deviating from the scope of the present disclosure. For instance, any of the doped regions may have a gradient dopant profile, stepped dopant profile, uniform dopant profile, non-uniform dopant profile, etc.

Aspects of the present disclosure are directed to implementing heterodoped layers in silicon carbide based devices, such as the trench gate MOSFET device of FIG. 1A, the planar gate MOSFET device 120 of FIG. 1B, and/or the Schottky diode device 140 of FIG. 1C, or other suitable devices, such as IGBTs, JFETs and FinFETs.

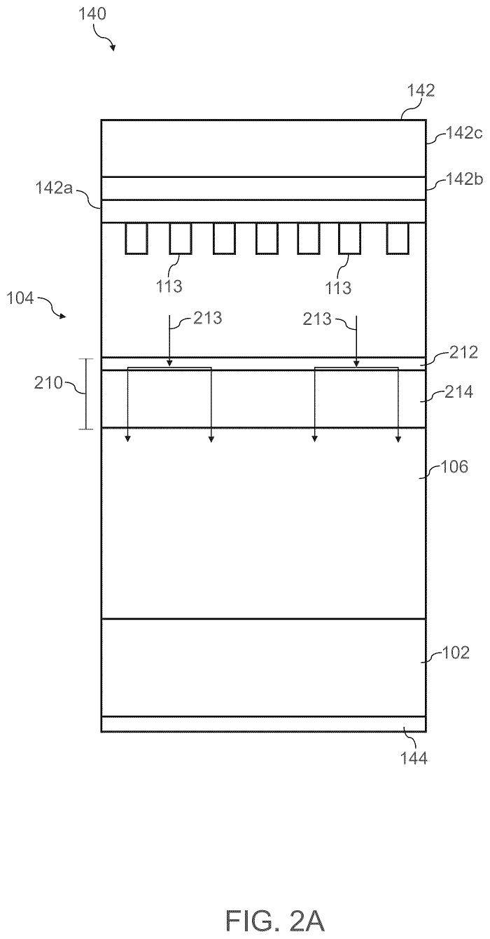

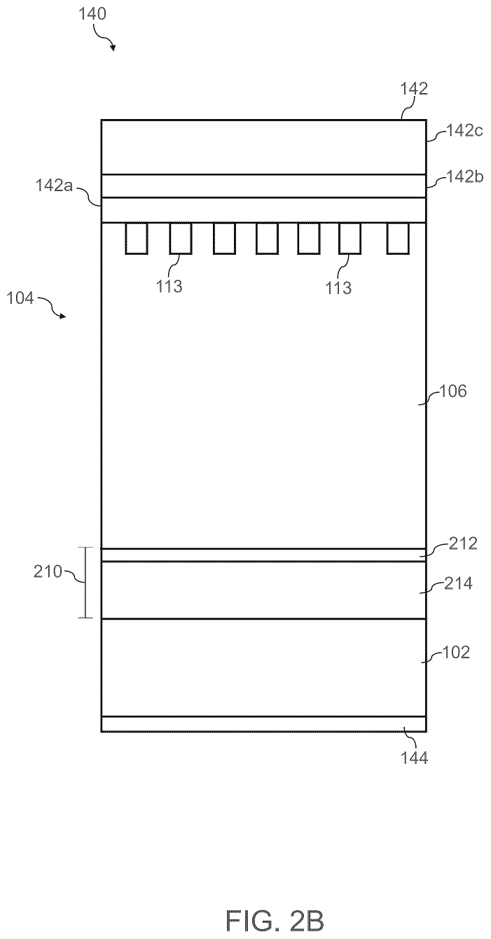

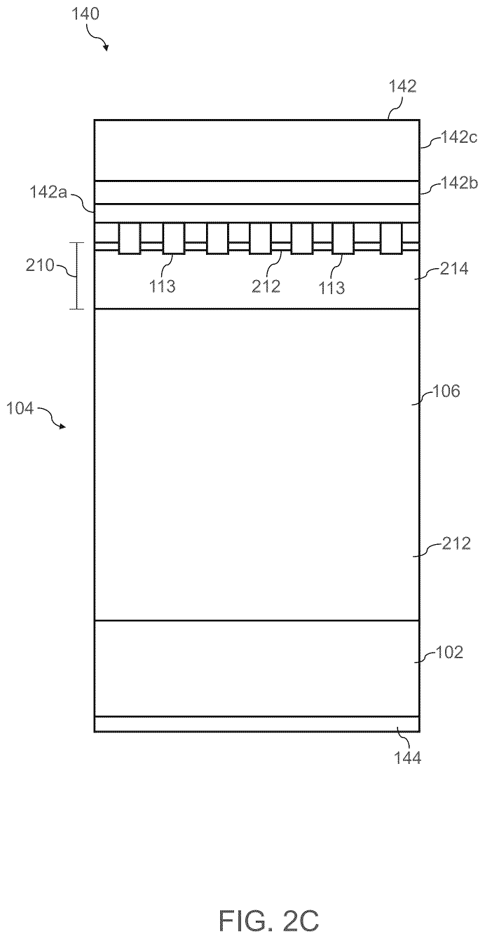

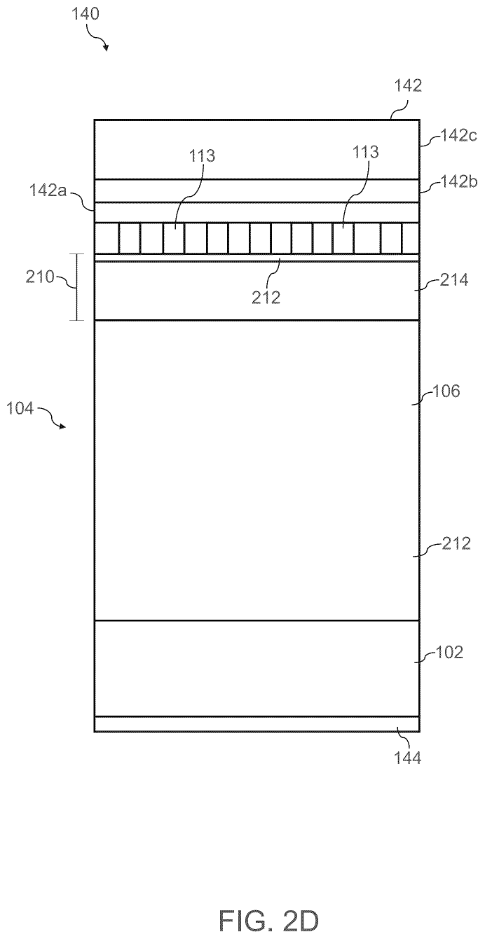

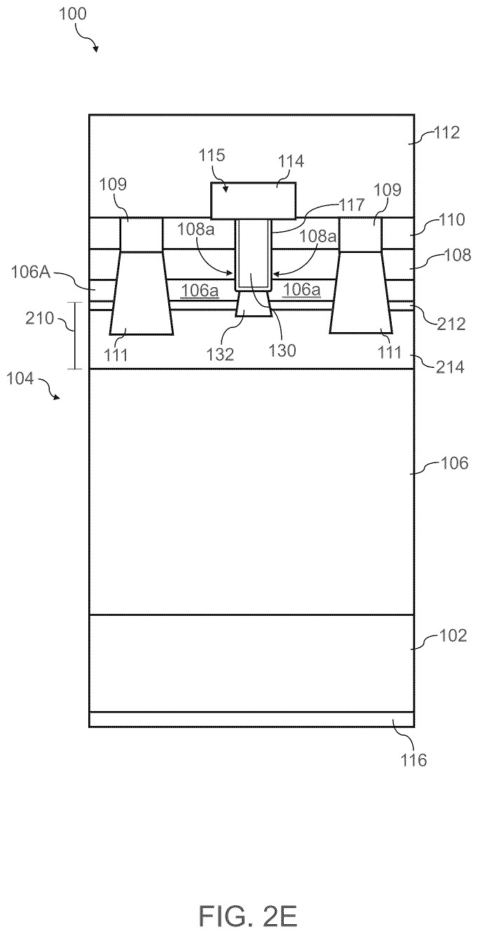

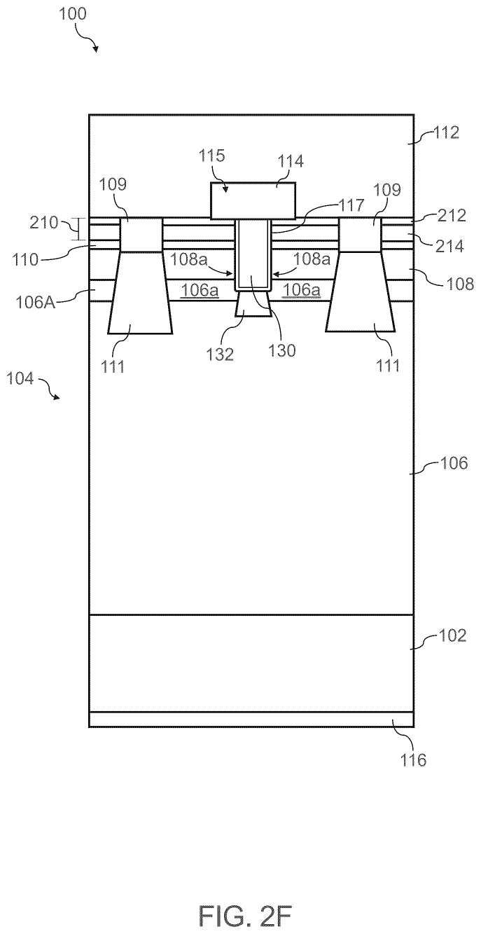

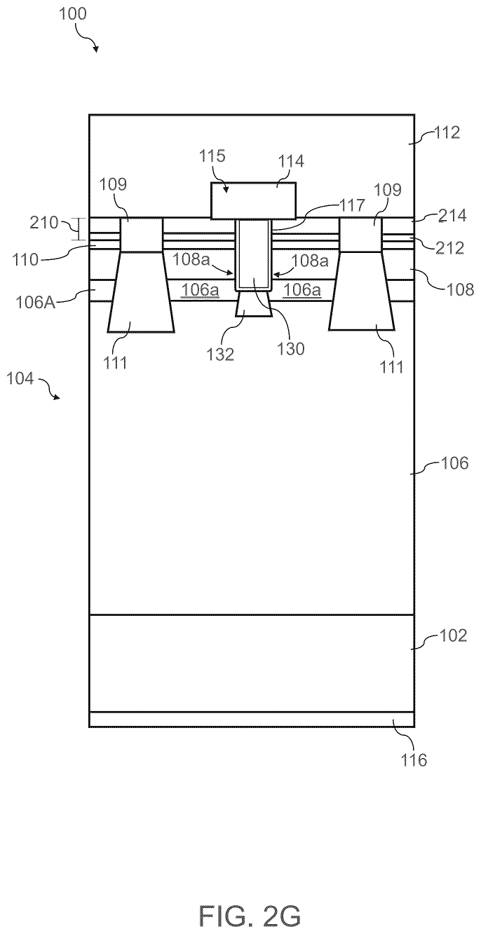

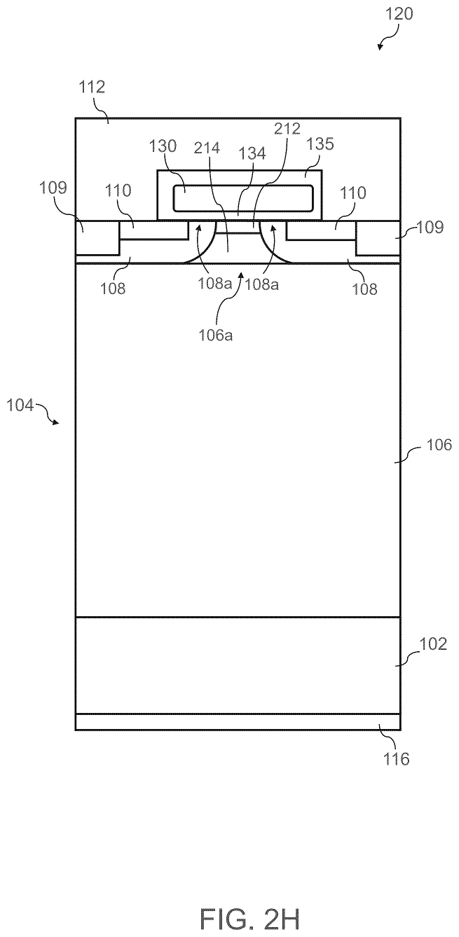

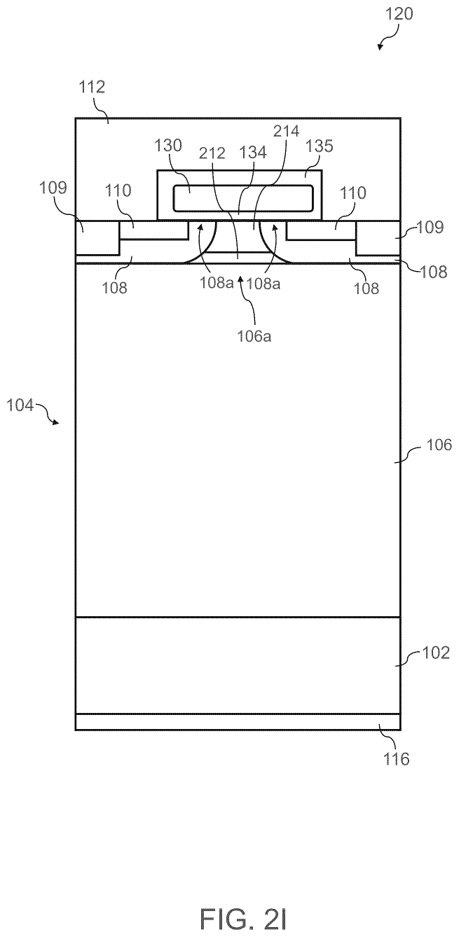

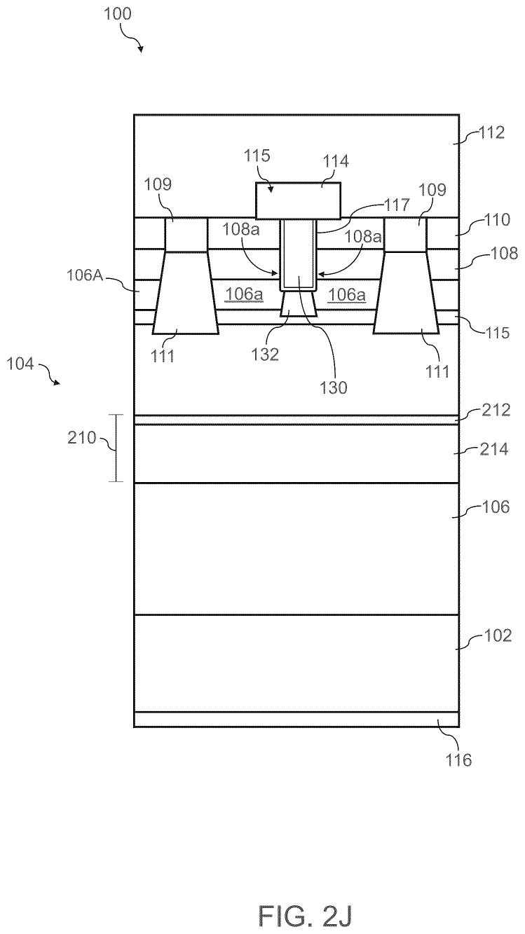

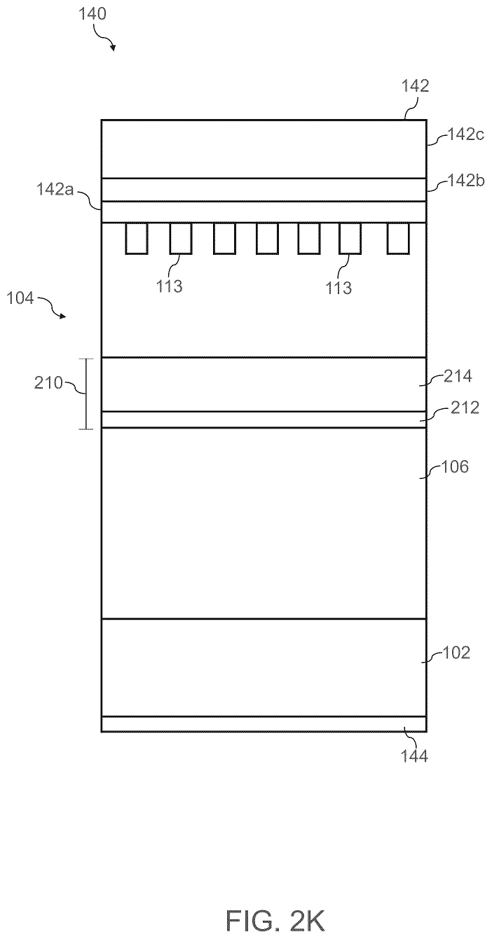

As shown in FIG. 2A, the Schottky diode device 140 includes a heterodoped layer 210. As illustrated, the heterodoped layer 210 is in the drift region 106 of the semiconductor structure 104. The heterodoped layer 210 includes a first layer 212 having a very high dopant concentration of dopants of a first conductivity type (e.g., n-type dopants, such as nitrogen dopants). The first layer 212 may be an “n++ layer.” For instance, a first dopant concentration of dopants of the first conductivity type in the first layer 212 may be in the range of about 1×10¹⁷/cm³ to about 2×10²¹/cm³, such as in the range of 1×10¹⁷/cm³ to about 1×10²⁰/cm³, such as in the range of about 1×10¹⁷/cm³ to about 3×10¹⁹/cm³, such as in a range of about 1×10¹⁷/cm³ to about 5×10¹⁸/cm³, such as in a range of about 5×10¹⁷/cm³ to about 5×10¹⁸/cm³. The heterodoped layer 210 may have a second layer 214. The second layer 214 may have a second dopant concentration of dopants of the first conductivity type that is less than first dopant concentration. The second layer 214 may be an “n-layer”. In some examples, the second dopant concentration may have, for instance, a dopant concentration in a range of about 1×10¹³/cm³ to about 5×10¹⁵/cm³, such as about 5×10¹³/cm³ to about 5×10¹⁵/cm³, such as in a range of about 1×10¹⁴/cm³ to about 5×10¹⁵/cm³, such as in a range of about 5×10¹⁴/cm³ to about 5×10¹⁵/cm³.

Depending on the embodiment, the heterodoped layer can comprise a first layer with higher doping (e.g., about 1×10¹⁷/cm³ to about 2×10²¹/cm³, such as in the range of 1×10¹⁷/cm³ to about 1×10²⁰/cm³, such as in the range of about 1×10¹⁷/cm³ to about 3×10¹⁹/cm³, such as in a range of about 1×10¹⁷/cm³ to about 5×10¹⁸/cm³, such as in a range of about 5×10¹⁷/cm³ to about 5×10¹⁸/cm³) and a second layer with lower doping (e.g., 1×10¹³/cm³ to about 5×10¹⁵/cm³, such as about 5×10¹³/cm³ to about 5×10¹⁵/cm³, such as about 1×10¹⁴/cm³ to about 5×10¹⁵/cm³, such as about 5×10¹⁴/cm³ to about 5×10¹⁵/cm³, or undoped) where a total electrical charge for the heterodoped layer can be adjusted to be equivalent to a semiconductor structure with an intermediate uniform doping level (e.g., about 1×10¹⁶/cm³ to about 5×10¹⁶/cm³) that is lower than the first doping concentration but with improved snappiness. Depending on the embodiment, using a heterodoped layer(s) with a relatively thin higher doped layer adjacent a thicker lower doped layer can achieve an electric charge equivalent to a SiC structure with a uniform intermediate doping (e.g., about 1×10¹⁶/cm³ to about 5×10¹⁶/cm³). As a result, the thicker lower doped layer can provide a longer mean free path for minority carriers so that the snappiness of the device is improved. Moreover, depending on the embodiment, the heterodoped layer can serve as a current spreading layer along the first highly doped layer when the majority carriers flow into the highly doped first layer and meet higher resistance in the second lower doped layer. The heterodoped layer may also provide strain compensation and defect termination. These effects may be increased by using multiple and/or repeating heterodoped layers.

In some examples, the second layer 214 may include a dopant concentration that is less than a dopant concentration of the drift region 106. For instance, the drift region 106 may have a third dopant concentration of dopants of a first conductivity type (such that the drift region is an n-type region). The third dopant concentration may be less than the first dopant concentration of the first layer 212. The third dopant concentration may be greater than the second dopant concentration of the second layer 214. The third dopant concentration may be, for instance, in a range of about 5×10¹⁵ to about 5×10¹⁶/cm³.

In some embodiments, the first layer 212 may be very thin relative to the semiconductor structure 104 and/or relative to the second layer 214 of the heterodoped layer 210. For instance, the first layer 212 may have a first thickness in a range of about 10 nanometers (nm) to about 200 nm, such as about 50 nanometers to about 175 nanometers. The second layer 214 may have a second thickness that is greater than the first thickness, such as at least twice the first thickness, such as at least five times the first thickness, such as at least 10 times the first thickness, such as in a range of about 20 nanometers or 0.02 microns to about 4 microns, such as about 0.04 microns to about 3 microns, from about 0.05 microns to about 2 microns, from about 0.1 microns to about 1.5 micron, from about 0.04 micron to about than 0.75 microns.

In some examples, the first layer 212 and/or the second layer 214 of the heterodoped layer 210 may have a graded distribution or other varying distribution of dopants across a thickness of the region. For instance, the distribution of dopants across the thickness of the second layer 214 may be such that a minimum dopant concentration is at an area adjacent to the first layer 212 of the heterodoped layer 210. This may provide a sharp contrast in dopant concentration at an interface between the first layer 212 (e.g., n++) and the second layer 214 (e.g., n−), which may lead to enhanced current spreading effects of the first layer 210 in the semiconductor structure. For instance, a current 213 through the drift region 106 of the semiconductor structure 104 may be spread laterally across the drift region 106 at an interface between the first layer 212 and the second layer 214.

In some examples, the heterodoped layer 210, including the first layer 212 and the second layer 214 may be formed by epitaxial growth. For instance, different dopant concentrations may be provided to the first layer 212 and the second layer during epitaxial growth of the semiconductor structure 104 to form the heterodoped layer 210.

In some examples, the heterodoped layer 210 may include a compensating component. For instance, the first layer 212 of the heterodoped layer 210 may include a compensating component. The compensating component may be, for instance, one or more of germanium, tin, arsenic, or phosphorus. The compensating component may be provided as dopants to the silicon carbide. However, in some embodiments, the compensating component may be alloyed with the silicon carbide (e.g., silicon carbide alloyed with germanium). In some embodiments, the heterodoped layer (e.g., the first layer 212 of the heterodoped layer) may include the compensating component to provide for bandgap engineering of the semiconductor structure 104. For instance, current spreading and/or snappiness effects may be improved by modifying the bandgap of the semiconductor structure in the first layer of the heterodoped layer.

In some embodiments, a concentration of the compensating component is about 1×10¹⁷/cm³ to about 2×10²¹/cm³. In some embodiments, the concentration of the compensating component is from about 2×10¹⁷/cm³ to about 2×10²⁰/cm³. In some embodiments, the concentration of the compensating component is from about 2×10¹⁷/cm³ to about 1.8×10²⁰/cm³. In some embodiments, the concentration of the compensating component is from about 2×10¹⁷/cm³ to about 1×10²⁰/cm³. In some embodiments, the concentration of the compensating component is from about 1×10¹⁸/cm³ to about 1.8×10²⁰/cm³. In some embodiments, the concentration of the compensating component is from about 1×10¹⁸/cm³ to about 1.8×10¹⁹/cm³. In some embodiments, the concentration of the compensating component is from about 1×10¹⁸/cm³ to about 1×10¹⁹/cm³.

Variations and modifications may be made to the embodiment of FIG. 2A without deviating from the scope of the present disclosure. For instance, the heterodoped layer 210 may be located anywhere in the semiconductor structure 104 without deviating from the scope of the present disclosure. For instance, FIG. 2B depicts the heterodoped layer 210 at a location in the drift region 206 proximate to or in contact with the substrate 102. Note, depending on the embodiment, intervening layers may be present that are not shown. The heterodoped layer 210 includes a first layer 212 and a second layer 214 as described with reference to FIG. 2A.

FIG. 2C depicts the heterodoped layer 210 that is at least partially within a “active structure” 205 of the semiconductor structure 104. The heterodoped layer 210 includes a first layer 212 and a second layer 214 as described with reference to FIG. 2A. The active structure 205 may be the portion of the semiconductor structure 104 that includes doped regions (e.g., Schottky junction barrier regions 113) near the surface of the semiconductor structure 104. As shown, the heterodoped layer 210 is at least partially located within the active structure 205 (e.g., extending between Schottky junction barrier regions) of the semiconductor structure 104. More particularly, the first layer 212 is at least partially in the active structure 205 and intersects with the Schottky junction barrier regions 113 of the Schottky diode semiconductor device 140.

FIG. 2D depicts a Schottky diode device 140 that is similar to the semiconductor device 140 of FIG. 2C. However, FIG. 2D depicts the heterodoped layer in a region immediately below the Schottky junction barrier regions 113 in the semiconductor structure 104 and therefore below the active structure 205.

FIG. 2E depicts the heterodoped layer 210 that is at least partially within the active structure 205 of the trench gate MOSFET device 100 of FIG. 1A. More particularly, the heterodoped layer 210 is at least partially in the JFET region 106a. The doped portions (e.g., the p-type well region 108, the n-type source region 110, the p-type contact regions 109, etc.) near the surface of the semiconductor structure 104 as well as the channel region 108a and the JFET region 106a may be referred to as the active structure 205 of the semiconductor device 100.

FIG. 2F depicts the heterodoped layer 210 that is entirely within the active structure 205 of the trench gate MOSFET device 100 of FIG. 1A. More particularly, the heterodoped layer 210 is within the source region 110. In the example embodiment of FIG. 2F, the first layer 212 of higher dopant concentration is closer to the surface of the semiconductor structure 104 relative to the second layer 214.

FIG. 2G depicts the heterodoped layer 210 that is entirely within the active structure 205 of the trench gate MOSFET device 100 of FIG. 1A. More particularly, the heterodoped layer is within the source region 110. In the example embodiment of FIG. 2G, the second layer 214 of lower dopant concentration is closer to the surface of the semiconductor structure 104 relative to the first layer 212. Providing the second layer 214 closer to the surface may reduce leakage effects from having high dopants, for instance, in a termination region of the semiconductor device 100 or breakdown from having high electrical charge close to the gate dielectric (e.g., gate oxide).

FIG. 2H depicts a heterodoped layer 210 that is at least partially within the active structure 205 of the planar gate MOSFET semiconductor device 120 of FIG. 1B. More particularly, the heterodoped layer 210 is at least partially in the JFET region 106a (e.g., at the thinnest point of the JFET region 106a or other location within the JFET region 106a. In the embodiment of FIG. 2H, the first layer 212 is closer to the surface of the semiconductor device 120 relative to the second layer 214. The doped portions (e.g., the p-type well region 108, the n-type source region 110, the p-type contact regions 109, etc.) near the surface of the semiconductor structure 104 as well as the JFET region 106a and channel region 108a may be referred to as the active structure 205 of the semiconductor device 120.

FIG. 2I depicts a heterodoped layer 210 that is at least partially within the active structure 205 of the planar gate MOSFET semiconductor device 120 of FIG. 1B. More particularly, the heterodoped layer 210 is at least partially in the JFET region 106a (e.g., at the thinnest point of the JFET region 106a or other location within the JFET region 106a. In the embodiment of FIG. 2H, the first layer 212 is closer to the surface of the semiconductor device 120 relative to the second layer 214. In the embodiment of FIG. 2I, the second layer 214 is closer to the surface of the semiconductor device 120 relative to the first layer 212. Providing the second layer 214 closer to the surface may reduce leakage effects from having high dopants, for instance, in a termination region of the semiconductor device 120 or breakdown from having high electrical charge close to the gate dielectric (e.g., gate oxide).

FIG. 2J depicts a semiconductor device 100 that is similar to the MOSFET semiconductor device 100 of FIG. 2E. However, the heterodoped layer 210 is in the drift region 106. The semiconductor structure 155 further include an additional current spreading layer 115 in the semiconductor structure 104. The current spreading layer 115 may be between the drift region 106 and the active structure 205. The heterodoped layer 210 is spaced apart from the current spreading layer 115. The current spreading layer 115 may have a dopant concentration of a first conductivity type (e.g., n-type dopants) that is greater than the doping concentration of the drift region 106 but less than the dopant concentration of the first layer 210 of the heterodoped layer.

Depending on the embodiment and on the desired application and operating conditions, the heterodoped layer may beneficially have the lower doped layer closer to the active structure while the higher doped layer is further from the active structure. FIG. 2K depicts the heterodoped layer 210 that has a second layer 214 at a location in the drift region 106 of the semiconductor structure 104 closer to the active structure relative to the substrate 102. The heterodoped layer 210 has a first layer at a location in the drift region 106 of the semiconductor structure 104 that is closer to the substrate 102 relative to the active structure.

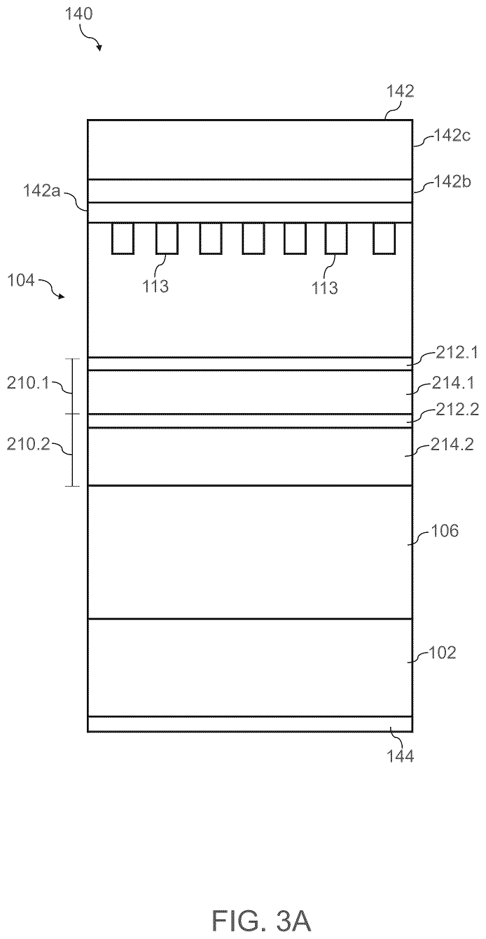

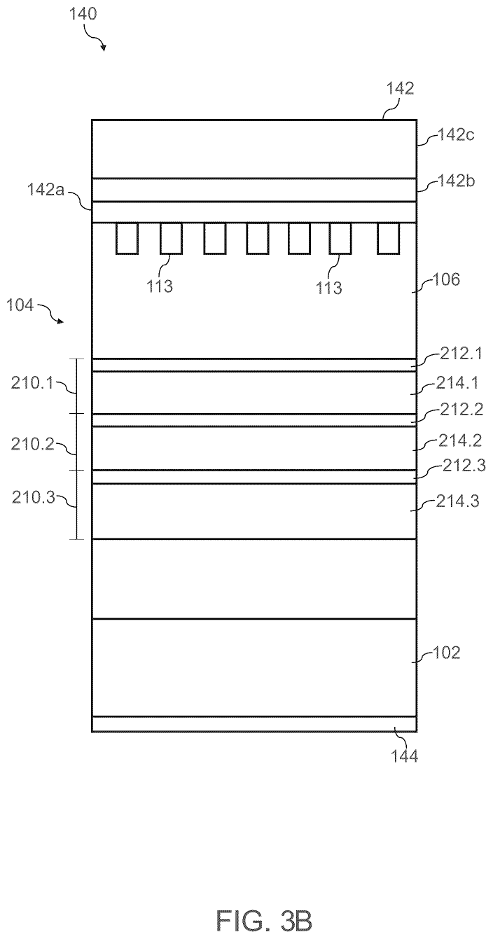

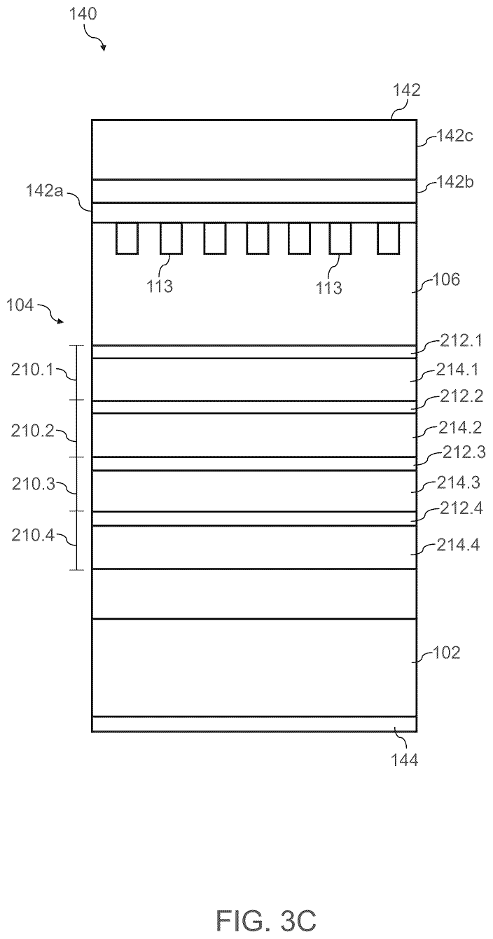

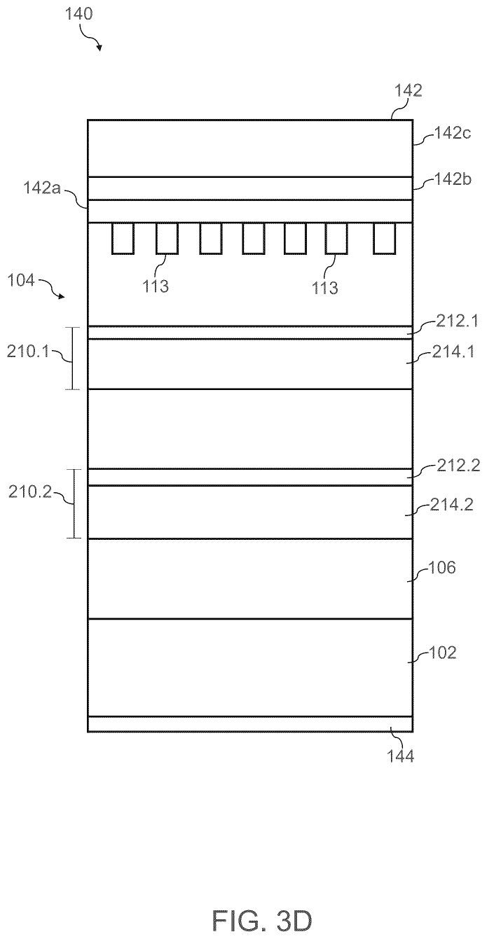

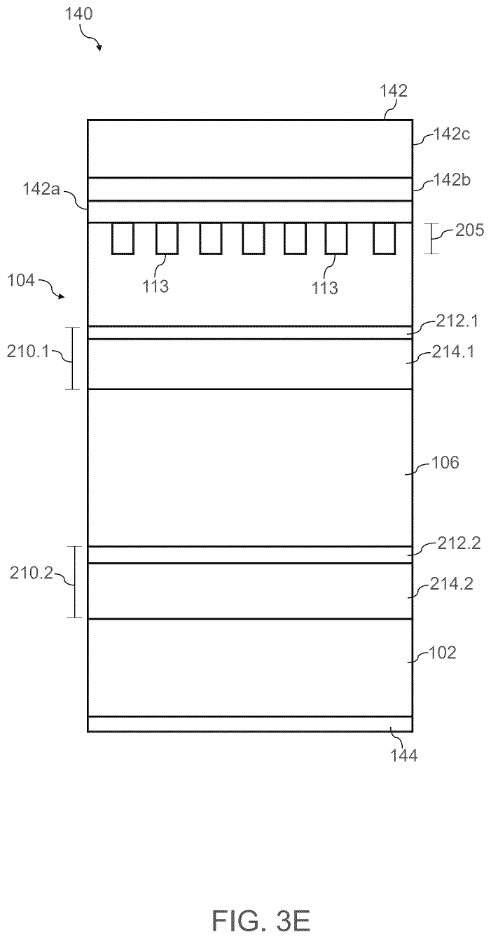

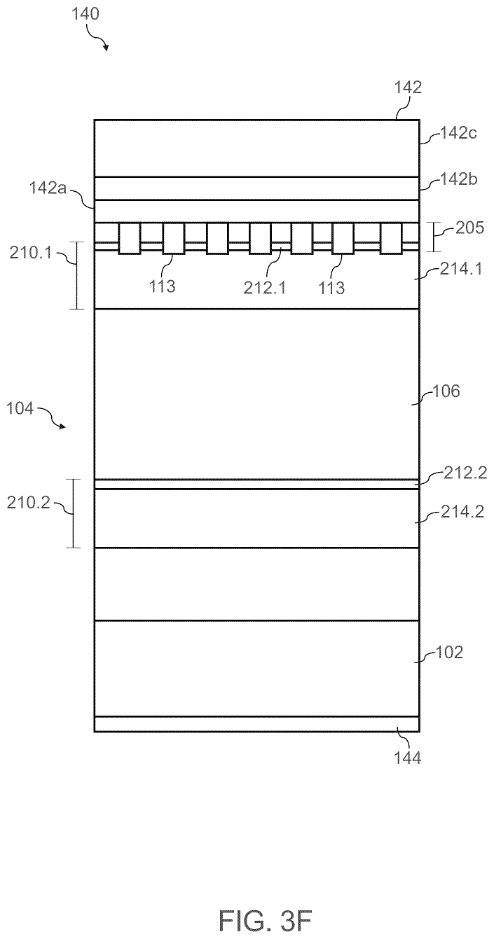

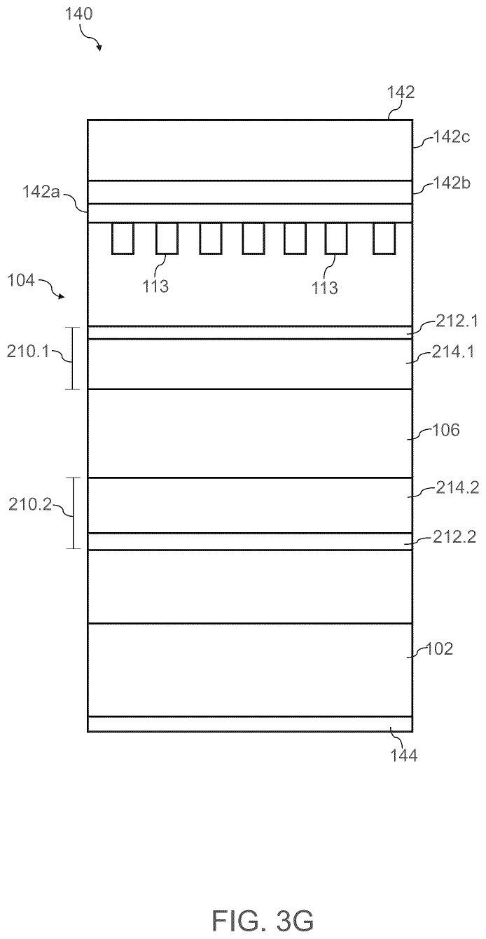

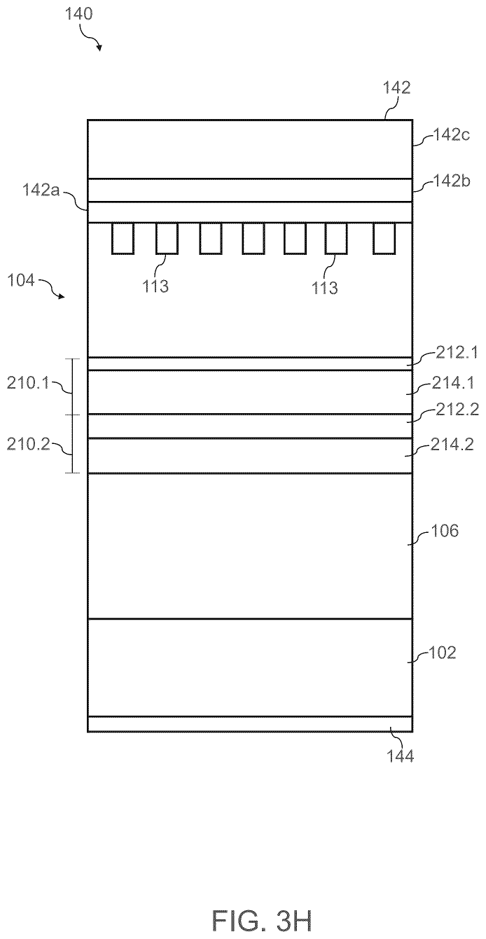

In some examples, a power semiconductor device may include a plurality of (e.g., two or more) heterodoped layers. For instance, FIG. 3A depicts a semiconductor device 140 having a first heterodoped layer 210.1 and a second heterodoped layer 210.2. The first heterodoped layer 210.1 may include a first layer 212.1 and a second layer 214.1. The second heterodoped layer 210.2 may include a first layer 212.2 and a second layer 214.2. The first layers 212.1, 212.2 may be like the first layer 212 of FIG. 2A. The second layers 214.1, 214.2 may be like the second layer 214 of FIG. 2A.

The first layers 212.1, 212.2 may have the same dopant concentration and/or the same thickness in some embodiments. However, in some embodiments, the first layers 212.1, 212.2 may have differing dopant concentrations and/or different thicknesses.

The second layers 212.1, 212.2 may have the same dopant concentration and/or the same thickness in some embodiments. However, in some embodiments, the first layers 212.1, 212.2 may have differing dopant concentrations and/or different thicknesses.

FIG. 3A depicts two heterodoped layers 210 for purposes of illustration and discussion. Those of ordinary skill in the art, using the disclosures provided herein, will understand that the semiconductor structure 104 may include any number of heterodoped layers without deviating from the scope of the present disclosure.

For instance, FIG. 3B depicts a semiconductor device 140 having three heterodoped layers 210.1, 210.2, 210.3. Each of the heterodoped layers may respectively include a first layer 212.1, 212.2, 212.3. Each of the heterodoped layers may respectively include a second layer 212.1, 212.2, 212.3. The first layers 212.1, 212.2, 212.3 may be like the first layer 212 of FIG. 2A. The second layers 214.1, 214.2, 214.3 may be like the second layer 214 of FIG. 2A.

For instance, FIG. 3C depicts a semiconductor device 140 having four heterodoped layers 210.1, 210.2, 210.3, 210.4 in a lattice structure. Each of the heterodoped layers may respectively include a first layer 212.1, 212.2, 212.3, 212.4. Each of the heterodoped layers may respectively include a second layer 212.1, 212.2, 212.3, 214.4. The first layers 212.1, 212.2, 212.3, 212.4 may be like the first layer 212 of FIG. 2A. The second layers 214.1, 214.2, 214.3, 214.4 may be like the second layer 214 of FIG. 2A. In some embodiments, the second layers 214.1, 214.2, 214.3, 214.4 may be undoped.

In FIG. 3A, the first heterodoped layer 210.1 and the second heterodoped layer 212.2 are contiguous or adjacent to one another in the drift region 106 of the semiconductor structure to form a lattice structure. However, the first heterodoped layer 210.1 and the second heterodoped layer 210.2 may be spaced apart from one another. Moreover, the first heterodoped layer 210.1 and the second heterodoped layer 210.2 may be located at any location in the semiconductor structure 104.

For instance, 3D depicts the first heterodoped layer 210.1 and the second heterodoped layer 210.2 being spaced apart from one another in the drift region 106 of the semiconductor structure 104. FIG. 3E depicts the first heterodoped layer 210.1 and the second heterodoped layer 210.2 being spaced apart from one another with the second heterodoped layer 210.2 being adjacent to the substrate 102. FIG. 3F depicts the first heterodoped layer 210.1 and the second heterodoped layer 210.2 being spaced apart with the first heterodoped layer 210.1 being in the active structure 205.

In some examples, the heterodoped layers 210.1, 210.2 may be oriented in different directions. For instance, FIG. 3G depicts a semiconductor device 140 with a first heterodoped layer 210.1 and a second heterodoped layer 210.2. The first heterodoped layer 210.1 may have a first layer 212.1 closer to the active structure 205 of the semiconductor device 140 relative to the second layer 214.1. The second layer 214.1 may be closer to the substrate 102 relative to the first layer 212.1. The second heterodoped layer 210.2 may have the opposite arrangement. For instance, the first layer 212.2 may be closer to the substrate 102 relative to the second layer 214.2. The second layer 214.2 may be closer to the active structure 205 relative to the first layer 212.2.

FIG. 3H depicts a semiconductor device 140 with a first heterodoped layer 210.1 and a second heterodoped layer 210.2. The first heterodoped layer 210.1 has a different size and/or thickness in the semiconductor structure 104 relative to the second heterodoped layer 210.2. For instance, in some embodiments, the first layer 212.1 may have a different thickness in the semiconductor structure 104 relative to the first layer 212.2. In addition and/or in the alternative, the second layer 214.1 may have a different thickness in the semiconductor structure 104 relative to the second layer 214.2.

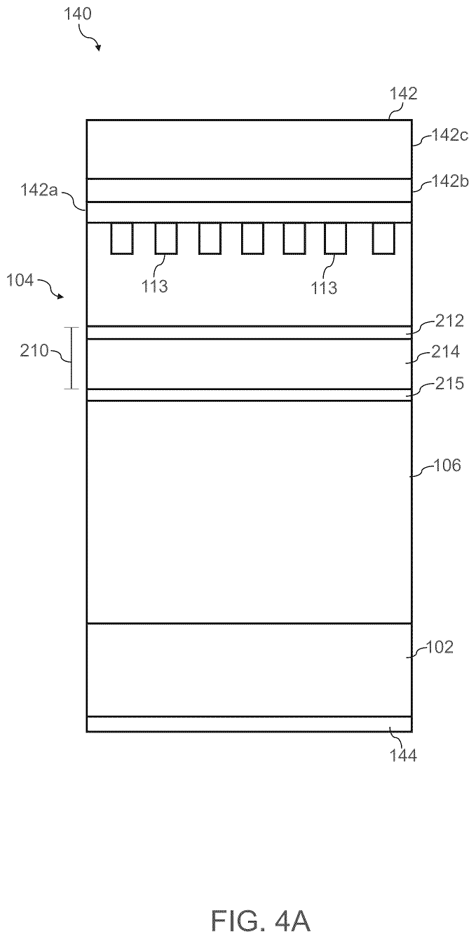

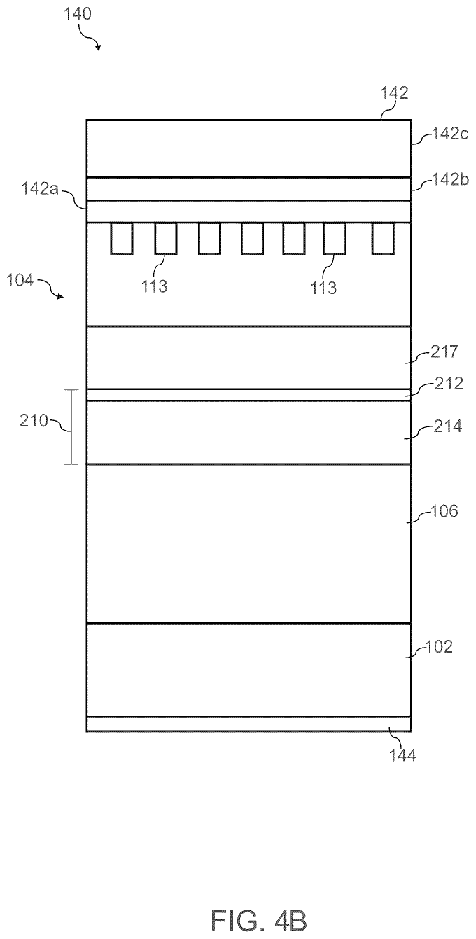

The heterodoped layers according to examples of the present disclosure may be adjacent other layers of high dopant concentration and/or layers of low dopant concentration without deviating from the scope of the present disclosure. For instance, FIG. 4A depicts a semiconductor device 140 including a heterodoped layer 210. The heterodoped layer 210 includes a first layer 212 and a second layer 214. The heterodoped layer 210 is adjacent a layer 215 of high dopant concentration that is similar to the first layer 212. In this way, the semiconductor structure 104 may include a second layer 214 between two first layers 212. The first layers 212 may be like the first layer 212 of FIG. 2A. The second layer 214 may be like the second layer 214 of FIG. 2A.

FIG. 4B depicts a semiconductor device 140 including a heterodoped layer 210. The heterodoped layer 210 includes a first layer 212 and a second layer 214. The heterodoped layer 210 is adjacent a layer 217 of low dopant concentration that is similar to the second layer 214. In this way, the semiconductor structure 104 includes a first layer 212 that is between the plurality of second layers 214. The first layer 212 may be like the first layer 212 of FIG. 2A. The second layers 214 may be like the second layer 214 of FIG. 2A.

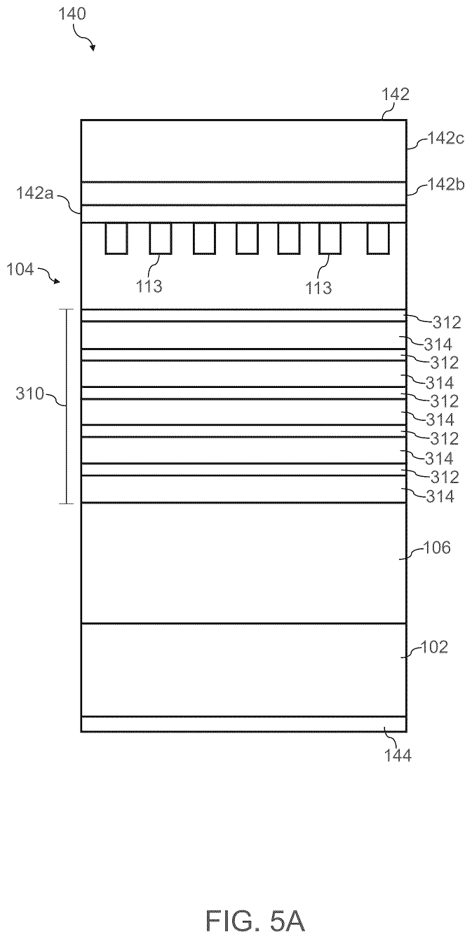

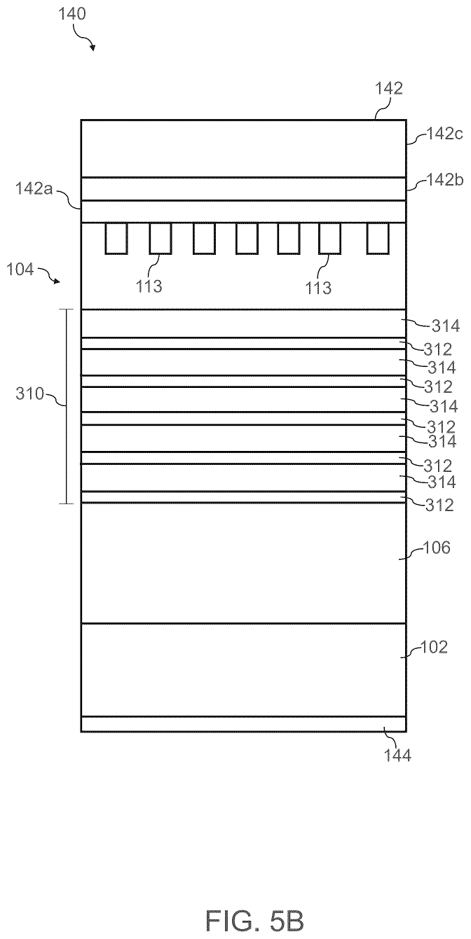

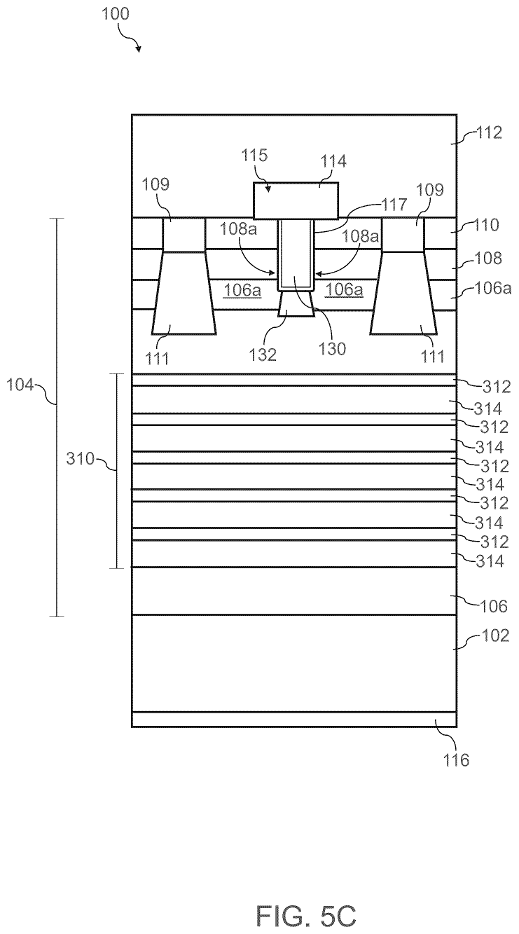

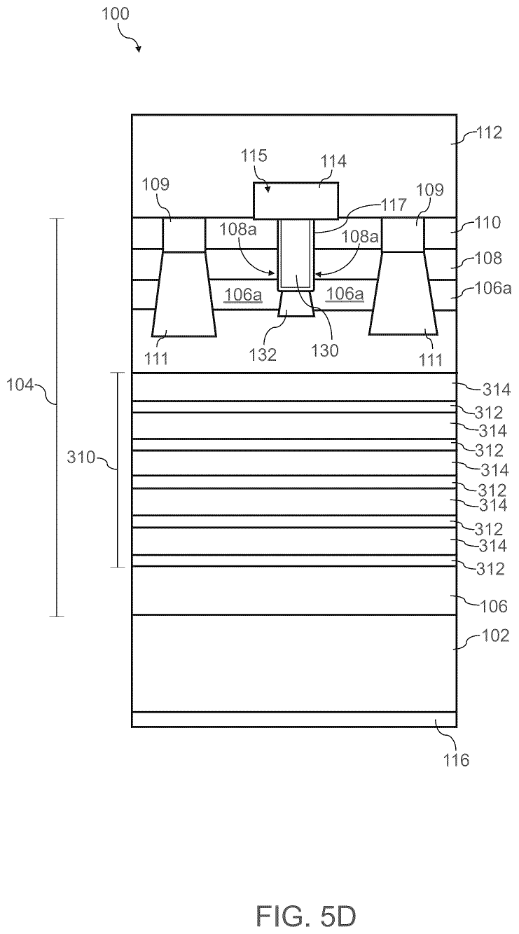

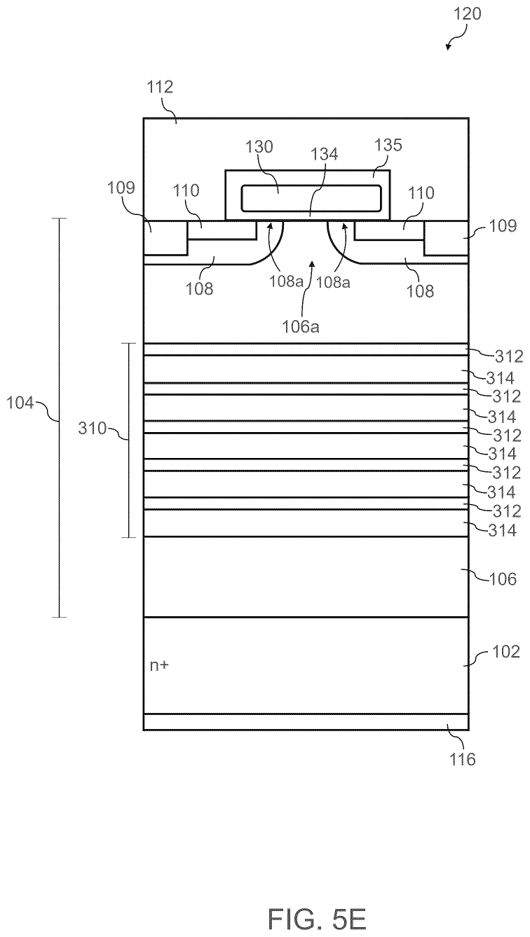

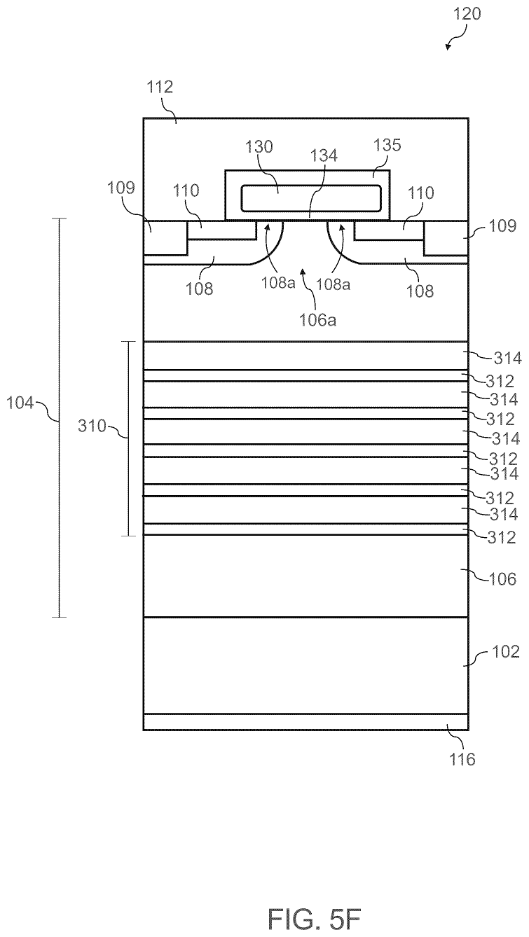

FIG. 5A depicts a semiconductor device 140 according to examples of the present disclosure. In the example of FIG. 5A, the semiconductor device 140 includes a heterodoped lattice structure 310. A heterodoped lattice structure 310 includes at least two first layers 312 and at least two second layers 314 arranged in an alternating manner through a thickness of the semiconductor structure 104 (e.g., the drift region 106). The doped regions of the heterodoped lattice structure 310 are contiguous with one another. The first layers 312 may be like the first layer 212 of FIG. 2A. The second layers 314 may be like the second layer 214 of FIG. 2A. in some examples, a total thickness of the heterodoped lattice structure may be less than 5 microns, such as less than 4 microns, such as less than 2 microns, such as less than one micron.

FIG. 5A depicts a heterodoped lattice structure 310 comprising five first layers 312 and five second layers 314 for purposes of illustration and discussion. Those of ordinary skill in the art, using the disclosures provided herein, will understand that a heterodoped lattice structure 310 may include any number of first layers 312 and second layers 314, such as two or more first layers 312 and second layers 314, such as ten or more first layers 312 and second layers 314, such as twenty or more first layers 312 and second layers 314.

FIG. 5A depicts a semiconductor device 140 with a heterodoped lattice structure 310 in a drift region 106 for purposes of illustration and discussion. Those of ordinary skill in the art, using the disclosures provided herein, will understand that the heterodoped lattice structure 310 may be in other areas of the semiconductor structure 104 without deviating from the scope of the present disclosure, such as at least partially in an active structure of the semiconductor structure 104 or adjacent to the substrate 102.

FIG. 5B depicts a semiconductor device 140 with a heterodoped lattice structure 310 similar to that of FIG. 5A. However, the positions of the first layers 312 and the second layers 314 of the heterodoped lattice structure 310 are reversed. More particularly, moving in a direction through the semiconductor structure 104 from the active structure to the substrate 102, the second layers 314 are on top of the first layers 312 and appear first in the heterodoped lattice structure 310. This is in contrast to FIG. 5A, where moving in a direction through the semiconductor structure 104 from the active structure to the substrate 102, the first layers 312 are on top of the first layers 314 and appear first in the heterodoped lattice structure 310. Depending on the embodiment the lattice structure 310 can have higher doped layers on both sides or start with a higher doped layer and end with a lower doped layer, or start with a lower doped layer and end with a lower doped layer.

FIG. 5C depicts a semiconductor device 100 that is a trench gate MOSFET with a heterodoped lattice structure 310 similar to that of FIG. 5A. FIG. 5D depicts a semiconductor device 100 that is a trench gate MOSFET with a heterodoped lattice structure similar to that of FIG. 5B. FIG. 5E depicts a semiconductor device 120 that is a planar gate MOSFET with a heterodoped lattice structure 310 similar to that of FIG. 5A. FIG. 5F depicts a semiconductor device 120 that is a planar gate MOSFET with a heterodoped lattice structure 310 similar to that of FIG. 5B.

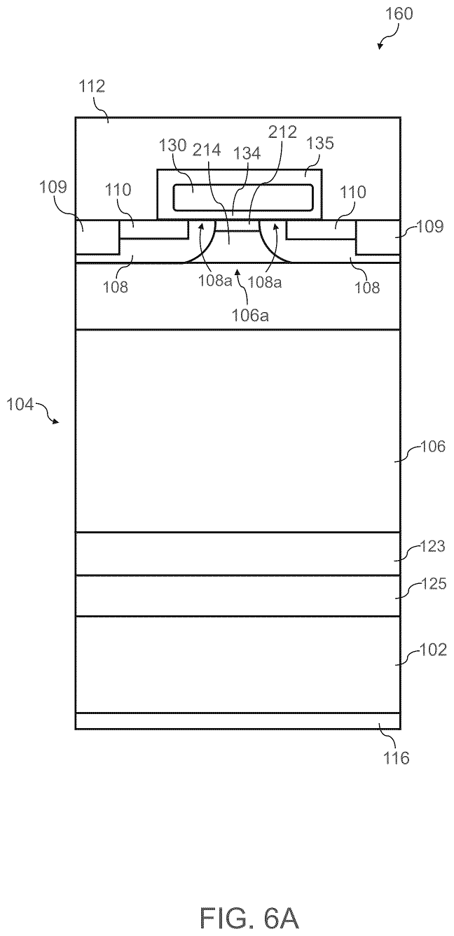

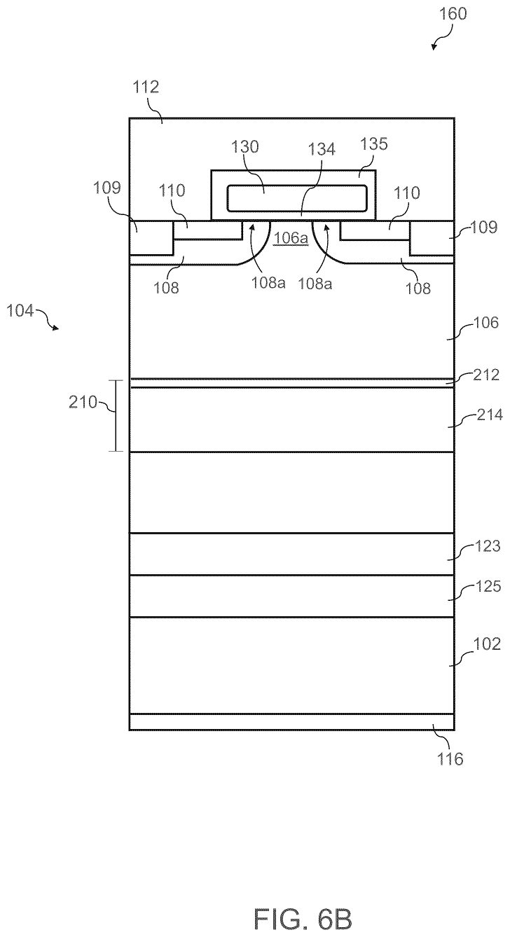

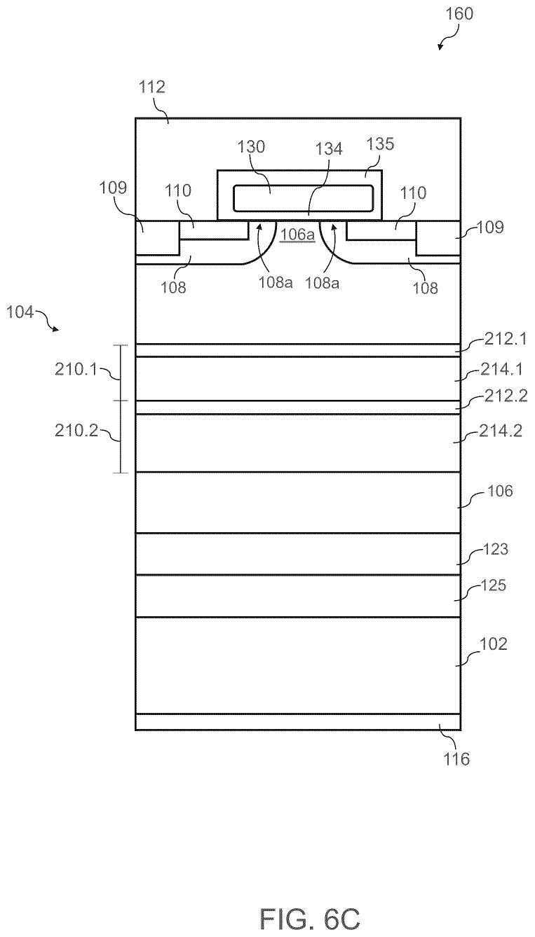

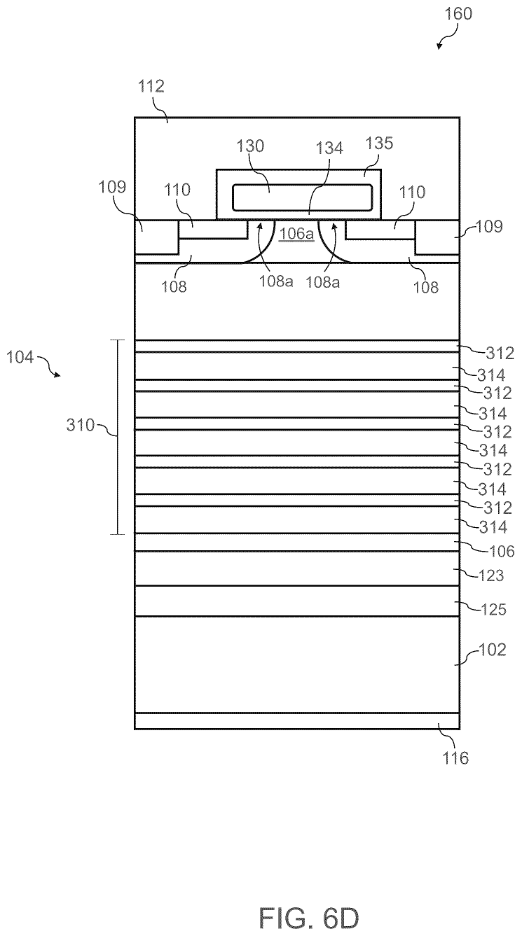

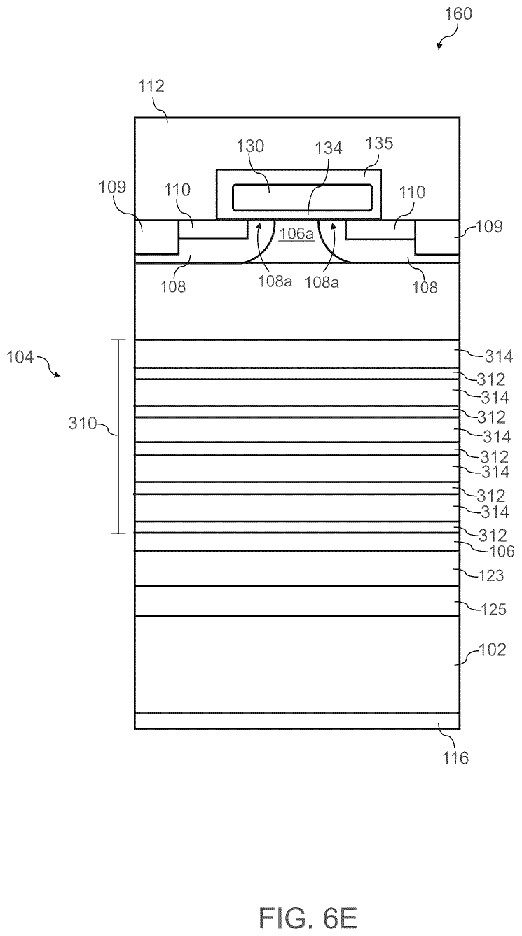

Any of the foregoing embodiments may be incorporated into different types of semiconductor devices, such as IGBTs. For instance, FIG. 6A depicts an IGBT 160 having a construction similar to that of the MOSFET device of FIG. 2E. However, the IGBT 160 includes a field stop layer 123 in the semiconductor structure 104 that is moderately doped with dopants of a first conductivity type (e.g., n-type. The IGBT 160 further includes a emitter layer 125 in the semiconductor structure that is highly doped with dopants of a second conductivity type (e.g., p-type). As shown in FIG. 6A, the IGBT 160 has a heterodoped layer 210 in the active structure 205 of the IGBT 160.

FIG. 6B depicts an IGBT 160 that is similar to the IGBT 160 of FIG. 6A. However, in FIG. 6B, the heterodoped layer 210 is in the drift region 106 of the IGBT 160 of FIG. 6B. FIG. 6C depicts an IGBT 160 that is similar to the IGBT 160 of FIG. 6A. However, in FIG. 6C, the IGBT 160 includes a plurality of heterodoped layers 210.1, 210.2. Those of ordinary skill in the art, using the disclosures provided herein, will understand that any of the embodiments of heterodoped layers may be used with the IGBT 160 without deviating from the scope of the present disclosure.

FIG. 6D depicts an IGBT 160 that is similar to the IGBT 160 of FIG. 6A. However, in FIG. 6D, the IGBT 160 includes a heterodoped lattice structure 310 similar to the heterodoped lattice structure 310 of FIG. 5A. FIG. 6E depicts an IGBT 160 that is similar to the IGBT 160 of FIG. 6B. However, in FIG. 6E, the IGBT 160 includes a heterodoped lattice structure 310 similar to the heterodoped lattice structure 310 of FIG. 5B.

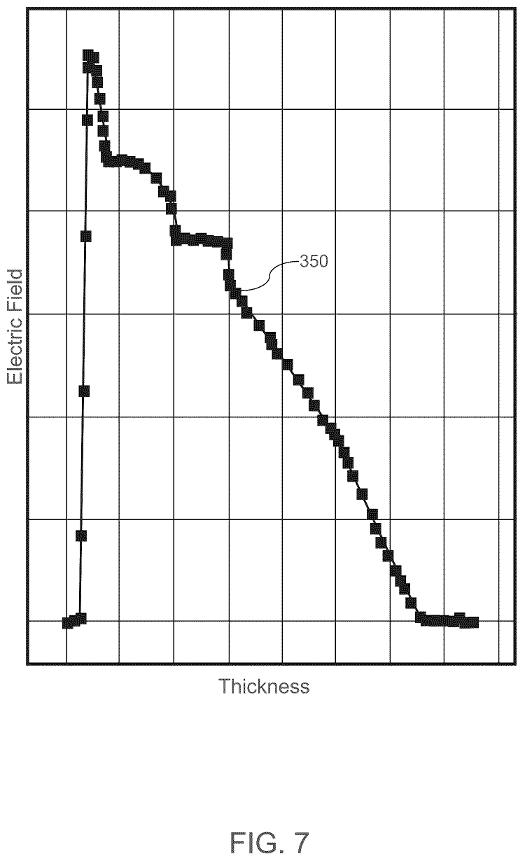

FIG. 7 depicts simulated electric field distribution through a thickness of the semiconductor structure 104 of the example semiconductor device 140 of FIG. 3A. FIG. 7 plots electric field on the vertical axis as a function of thickness (e.g., horizontal axis) through the semiconductor structure 104 of the example semiconductor device 140 of FIG. 3A. As demonstrated by curve 350, the electric field distribution is well distributed through the semiconductor structure 104 even with the presence of two heterodoped layers 210.1, 210.2. In addition, the semiconductor device 140 maintains a blocking voltage similar to a semiconductor structure 140 with no heterodoped layers.

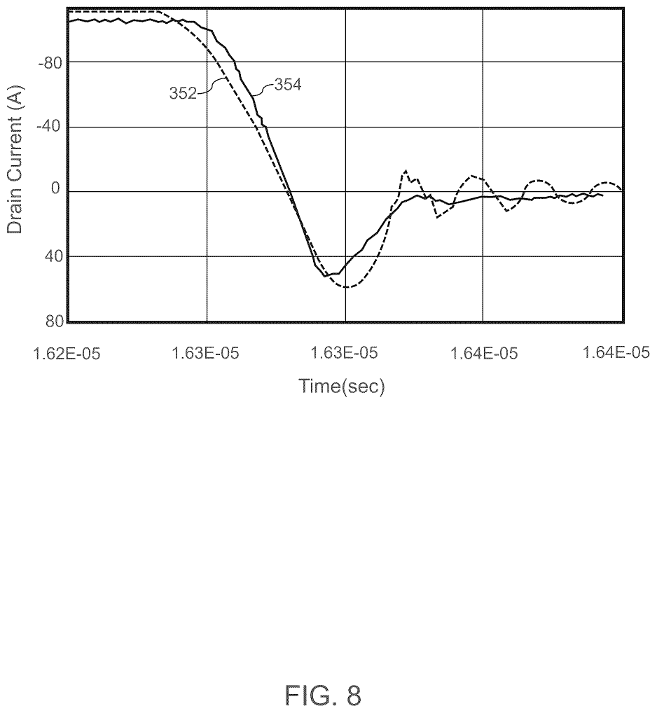

FIG. 8 depicts an example of diode snappiness improvement provided by incorporation of heterodoped layers according to examples of the present disclosure. FIG. 8 plots drain current (in Amperes) on the vertical axis as a function of time during a switching event in seconds on the horizontal axis. Curve 352 represents body diode snappiness of a typical silicon carbide MOSFET. Curve 354 represents improved body diode snappiness of a silicon carbide MOSFET having one or more heterodoped layers according to examples of the present disclosure.

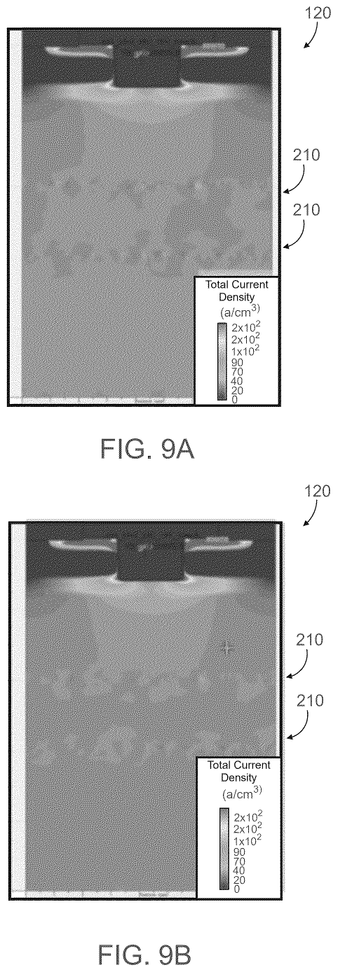

FIGS. 9A and 9B depict current distribution of an example semiconductor device of an example semiconductor device 100 (e.g., MOSFET) having a plurality of heterodoped layers 210. In the example of FIG. 9A, the heterodoped layers 210 each have a first layer (e.g., highly doped layer) having a dopant concentration of about 5×10¹⁷/cm³. In the example of FIG. 9B, the heterodoped layers 210 each have a first layer (e.g., highly doped layer) having a dopant concentration of about 1×10¹⁷/cm³. As can be seen from both FIGS. 9A and 9B, incorporation of heterodoped layers according to examples of the present disclosure may have significant current spreading effects.

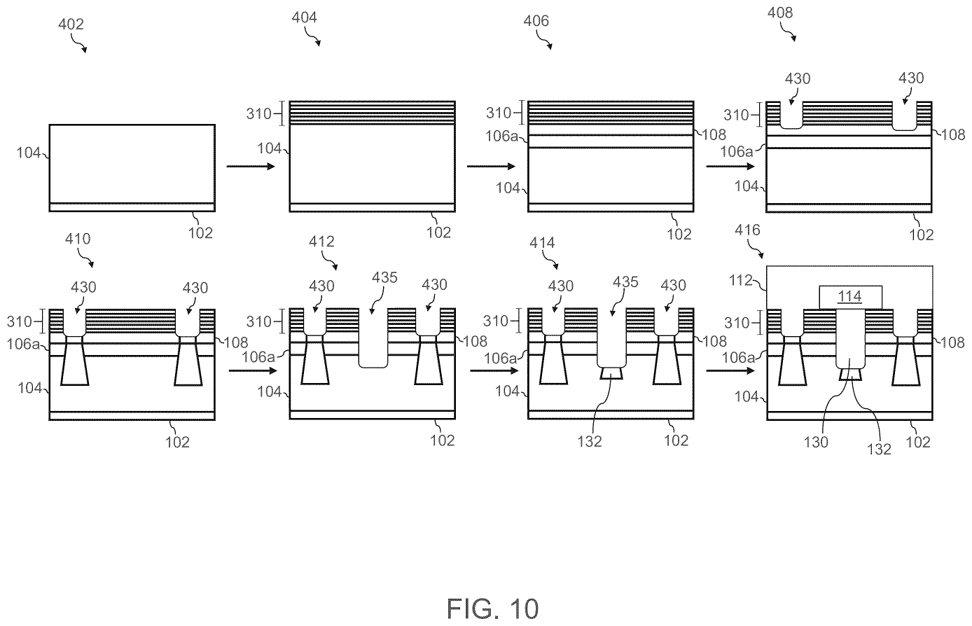

FIG. 10 depicts one example method 400 of forming a semiconductor device (e.g., a trench gate MOSFET 120) with a heterodoped lattice structure 310 in an active structure of the semiconductor device according to examples of the present disclosure. At 402, the method may include epitaxially growing a semiconductor structure 104 on a substrate 102.

At 404, the method may include epitaxially forming the heterodoped lattice structure 310 on the semiconductor structure 104. The heterodoped lattice structure 310 may be like the heterodoped lattice structure 310 of FIG. 5A.

At 406, the method may include forming the p-well region 108 and the JFET region 106a in the semiconductor structure 104. The p-well region 108 and the JEFT region 106a may be formed by dopant implantation, in some embodiments.

At 408, the method may include etching source trenches 430 in the semiconductor structure. The source trenches 430 may be etched using any suitable etch process, such as a plasma-based dry etch process or a wet etch process.

At 410, the method may include providing the highly doped p-type regions 111 in the semiconductor structure, for instance, at a location beneath the source trenches 430. The highly doped p-type regions 111 may be formed, for instance, using dopant implantation.

At 412, the method may include etching a gate trench 435. At 414, the method may include providing a p-type field shielding region 132 at a location beneath the gate trench 435, for instance, using ion implantation.

At 414, the method may include forming the gate structure 130 in the gate trench. The gate structure 130 may be a gate metal on a gate dielectric (e.g., gate oxide). The method may further include providing the source contact on the semiconductor structure 104 with an IMD layer between the gate structure 130.1 and the source contact.

Example aspects of the present disclosure are set forth below. Any of the below features or examples may be used in combination with any of the embodiments or features provided in the present disclosure.

In an aspect, the present disclosure provides an example power semiconductor device. In some implementations, the example power semiconductor device includes a silicon carbide semiconductor structure. In some implementations, the example power semiconductor device includes at least one heterodoped layer in the silicon carbide semiconductor structure. In some implementations, the heterodoped layer includes a first layer having a first dopant concentration of a first conductivity type in a range of about 1×10¹⁷/cm³ to about 2×10²¹/cm³. The heterodoped layer includes a second layer having a second dopant concentration of the first conductivity type that is less than the first dopant concentration of the first layer. In some implementations, the semiconductor structure includes a drift region. The drift region has a third dopant concentration of the first conductivity type. The third dopant concentration is less than the first dopant concentration.

In some implementations of the example power semiconductor device, the second layer has a dopant concentration in a range of about 1×10¹³/cm³ to about 5×10¹⁵/cm³.

In some implementations of the example power semiconductor device, the first layer has a first thickness in a range of about 10 nanometers to about 200 nanometers.

In some implementations of the example power semiconductor device, the second layer has a second thickness that is greater than the first thickness of the first layers.

In some implementations of the example power semiconductor device, the second thickness is at least twice the first thickness.

In some implementations of the example power semiconductor device, the second thickness is in a range of about 1 micron to about 4 microns.

In some implementations of the example power semiconductor device, the semiconductor device further comprises a substrate, wherein the heterodoped layer is closer to an active structure of the semiconductor structure relative to the substrate.

In some implementations of the example power semiconductor device, the third dopant concentration is greater than the second dopant concentration of the second layer.

In some implementations of the example power semiconductor device, the third dopant concentration is in a range of 5×10¹⁵/cm³ to 5×10¹⁶/cm³.

In some implementations of the example power semiconductor device, the heterodoped layer is adjacent an additional first layer such that the second layer of the heterodoped layer is between at least two first layers.

In some implementations of the example power semiconductor device, the heterodoped layer is adjacent an additional second layer such that the first layer of the heterodoped layer is between at least two second layers.

In some implementations of the example power semiconductor device, the second layer has a graded distribution of dopants across a thickness of the second layer.

In some implementations of the example power semiconductor device, the second layer has a minimum dopant concentration at an area adjacent to the first layer.

In some implementations of the example power semiconductor device, the power semiconductor device includes at least two heterodoped layers in the silicon carbide semiconductor structure.

In some implementations of the example power semiconductor device, the power semiconductor device includes five or more heterodoped layers in the semiconductor structure.

In some implementations of the example power semiconductor device, the semiconductor device further comprises a current spreading layer in the semiconductor structure.

In some implementations of the example power semiconductor device, the first layer includes a compensating component.

In some implementations of the example power semiconductor device, the compensating component includes germanium.

In some implementations of the example power semiconductor device, the compensating component includes one or more of tin, arsenic, or phosphorus.

In some implementations of the example power semiconductor device, a dopant associated with the first dopant concentration and the second dopant concentration includes a nitrogen dopant.

In some implementations of the example power semiconductor device, the heterodoped layer is in an active structure of the semiconductor structure.

In some implementations of the example power semiconductor device, the semiconductor structure includes epitaxial silicon carbide.

In some implementations of the example power semiconductor device, the semiconductor device is a MOSFET.

In some implementations of the example power semiconductor device, the semiconductor device is a Schottky diode.

In some implementations of the example power semiconductor device, the semiconductor device is an IGBT.

In an aspect, the present disclosure provides an example power semiconductor device. In some implementations, the example power semiconductor device includes a silicon carbide semiconductor structure. In some implementations, the example power semiconductor device includes at least one heterodoped layer in the silicon carbide semiconductor structure. In some implementations, the heterodoped layer includes a first layer having a first dopant concentration of a first conductivity type in a range of about 1×10¹⁷/cm³ to about 2×10²¹/cm³. The first layer has a first thickness in a range of about 10 nanometers to about 200 nanometers.

In some implementations of the example power semiconductor device, the heterodoped layer includes a second layer.

In some implementations of the example power semiconductor device, the second layer has a second dopant concentration in a range of about 1×10¹³/cm³ to about 5×10¹⁵/cm³.

In some implementations of the example power semiconductor device, the second layer has a second thickness that is greater than the first thickness of the first layer.

In some implementations of the example power semiconductor device, the second thickness is at least twice the first thickness.

In some implementations of the example power semiconductor device, the second thickness is in a range of about 1 micron to about 4 microns.

In some implementations of the example power semiconductor device, the semiconductor structure includes a drift region, wherein the drift region has a third dopant concentration of the first conductivity type.

In some implementations of the example power semiconductor device, the third dopant concentration is less than the first dopant concentration of the first layer and greater than the second dopant concentration of the second layer.

In some implementations of the example power semiconductor device, the third dopant concentration is in a range of 5×10¹⁵/cm³ to 5×10¹⁶/cm³.

In some implementations of the example power semiconductor device, the heterodoped layer is adjacent an additional first layer such that the second layer of the heterodoped layer is between at least two first layers.

In some implementations of the example power semiconductor device, the heterodoped layer is adjacent an additional second layer such that the first layer of the heterodoped layer is between at least two second layers.

In some implementations of the example power semiconductor device, the second layer has a graded distribution of dopants across a thickness of the second layer.

In some implementations of the example power semiconductor device, the second layer has a minimum dopant concentration at an area adjacent to the first layer.

In some implementations of the example power semiconductor device, the power semiconductor device includes at least two heterodoped layers in the silicon carbide semiconductor structure.

In some implementations of the example power semiconductor device, the power semiconductor device includes five or more heterodoped layers in the semiconductor structure.

In some implementations of the example power semiconductor device, the first layer includes a compensating component.

In some implementations of the example power semiconductor device, the compensating component includes germanium.

In some implementations of the example power semiconductor device, a dopant associated with the first dopant concentration includes a nitrogen dopant.

In some implementations of the example power semiconductor device, the heterodoped layer is in an active structure of the semiconductor structure.

In some implementations of the example power semiconductor device, the semiconductor structure includes epitaxial silicon carbide.

In some implementations of the example power semiconductor device, the semiconductor device is a MOSFET.

In some implementations of the example power semiconductor device, the semiconductor device is a Schottky diode.

In some implementations of the example power semiconductor device, the semiconductor device is an IGBT.

In an aspect, the present disclosure provides a semiconductor device. In some implementations, the example semiconductor device includes a silicon carbide semiconductor structure. The example semiconductor device includes a heterodoped lattice structure in the silicon carbide semiconductor structure. The heterodoped lattice structure includes at least two first layers having a first dopant concentration of a first conductivity type in a range of about 1×10¹⁷/cm³ to about 3×10¹⁹/cm³, wherein each first layer has a thickness in a range of about 10 nanometers to about 200 nanometers. The heterodoped lattice structure includes at least two second layers having a second dopant concentration of a first conductivity type that is less than the first dopant concentration of the plurality of first layers. The at least two first layers and the at least two second layers are arranged in alternating manner through a thickness of the silicon carbide semiconductor structure.

In some implementations of the example semiconductor device, the second layer has a dopant concentration in a range of about 1×10¹³/cm³ to about 5×10¹⁵/cm³.

In some implementations of the example semiconductor device, the second layer has a second thickness that is greater than the first thickness of the first layers.

In some implementations of the example semiconductor device, the second thickness is at least twice the first thickness.

In some implementations of the example semiconductor device, the second thickness is in a range of about 1 micron to about 4 microns.

In some implementations of the example semiconductor device, the semiconductor structure includes a drift region, wherein the drift region has a third dopant concentration of the first conductivity type.

In some implementations of the example semiconductor device, the third dopant concentration is less than the first dopant concentration of the first layer and greater than the second dopant concentration of the second layer.

In some implementations of the example semiconductor device, the third dopant concentration is in a range of 5×10¹⁵/cm³ to 5×10¹⁶/cm³.

In some implementations of the example semiconductor device, a dopant associated with the first dopant concentration and the second dopant concentration includes a nitrogen dopant.

In some implementations of the example semiconductor device, the heterodoped lattice structure is in an active structure of the semiconductor structure.

In some implementations of the example semiconductor device, the semiconductor structure includes epitaxial silicon carbide.

In some implementations of the example semiconductor device, the semiconductor device is a MOSFET.

In some implementations of the example semiconductor device, the semiconductor device is a Schottky diode.

In some implementations of the example semiconductor device, the semiconductor device is an IGBT.

In an aspect, the present disclosure provides an example silicon carbide semiconductor device. In some implementations, the example silicon carbide semiconductor device includes a silicon carbide epitaxial semiconductor structure. In some implementations, the example silicon carbide semiconductor device includes a drift region in the epitaxial semiconductor structure. In some implementations, the example silicon carbide semiconductor device includes a heterodoped layer in the epitaxial semiconductor structure. The heterodoped layer includes a first layer having a first dopant concentration of a first conductivity type in a range of about 1×10¹⁷/cm³ to about 3×10¹⁹/cm³, wherein the first layer has a thickness in a range of about 10 nanometers to about 200 nanometers. In some implementations, the example silicon carbide semiconductor device includes at least two well regions, each well region comprising dopants of a second conductivity type.

In some implementations of the example silicon carbide semiconductor device, the heterodoped layer is in the drift region.

In some implementations of the example silicon carbide semiconductor device, the heterodoped layer is at least partially between at least two well regions.

In some implementations of the example silicon carbide semiconductor device, the heterodoped layer includes a second layer having a dopant concentration in a range of about 1×10¹³/cm³ to about 5×10¹⁵/cm³.

In some implementations of the example silicon carbide semiconductor device, the second layer has a second thickness that is greater than the first thickness of the first layers.

In some implementations of the example silicon carbide semiconductor device, second thickness is at least twice the first thickness.

In some implementations of the example silicon carbide semiconductor device, the second thickness is in a range of about 1 micron to about 4 microns.

In some implementations of the example silicon carbide semiconductor device, the semiconductor structure includes a drift region, wherein the drift region has a third dopant concentration of the first conductivity type.

In some implementations of the example silicon carbide semiconductor device, the third dopant concentration is less than the first dopant concentration of the first layer and greater than the second dopant concentration of the second layer.

In some implementations of the example silicon carbide semiconductor device, the third dopant concentration is in a range of 5×10¹⁵/cm³ to 5×10¹⁶/cm³.

In some implementations of the example silicon carbide semiconductor device, the heterodoped layer is adjacent an additional first layer such that the second layer of the heterodoped layer is between at least two first layers.

In some implementations of the example silicon carbide semiconductor device, the heterodoped layer is adjacent an additional second layer such that the first layer of the heterodoped layer is between at least two second layers.

In some implementations of the example silicon carbide semiconductor device, the second layer has a graded distribution of dopants across a thickness of the second layer.

In some implementations of the example silicon carbide semiconductor device, the second layer has a minimum dopant concentration at an area adjacent to the first layer.

In some implementations of the example silicon carbide semiconductor device, the silicon carbide semiconductor device includes at least two heterodoped layers.

In some implementations of the example silicon carbide semiconductor device, the silicon carbide semiconductor device includes five or more heterodoped layers in the semiconductor structure.

In some implementations of the example silicon carbide semiconductor device, the first layer includes a compensating component.

In some implementations of the example silicon carbide semiconductor device, the compensating component includes germanium

In some implementations of the example silicon carbide semiconductor device, a dopant associated with the first dopant concentration includes a nitrogen dopant.

In some implementations of the example silicon carbide semiconductor device, the heterodoped layer is in an active structure of the semiconductor structure.

In some implementations of the example silicon carbide semiconductor device, the semiconductor structure includes a current spreading layer.

In some implementations of the example silicon carbide semiconductor device, the semiconductor device is a MOSFET.

In some implementations of the example silicon carbide semiconductor device, the semiconductor device is a Schottky diode.

In some implementations of the example silicon carbide semiconductor device, the semiconductor device is an IGBT.

In an aspect, the present disclosure provides an example power semiconductor device. In some implementations, the example power semiconductor device includes a silicon carbide semiconductor structure. In some implementations, the example power semiconductor device includes at least one heterodoped layer in the silicon carbide semiconductor structure. In some implementations, the heterodoped layer includes a first layer having a thickness of about 10 nm to about 200 nm, the first layer having a first dopant concentration of a first conductivity type. The heterodoped layer includes a second layer having a second dopant concentration of the first conductivity type. In some implementations, the first dopant concentration is at least 30 times greater than the second dopant concentration.

In some implementations of the example power semiconductor device, the first dopant concentration is in a range of about 30 times greater to about 60 times greater than the second dopant concentration.

In some implementations of the example power semiconductor device, the first dopant concentration is in a range of about 30 times greater to about 40 times greater than the second dopant concentration.

In some implementations of the example power semiconductor device, the first dopant concentration is in a range of about 30 times greater to about 35 times greater than the second dopant concentration.

In some implementations of the example power semiconductor device, the second layer has a second thickness that is greater than the first thickness of the first layers.

In some implementations of the example power semiconductor device, second thickness is at least twice the first thickness.

In some implementations of the example power semiconductor device, the semiconductor structure includes epitaxial silicon carbide.

In some implementations of the example power semiconductor device, the semiconductor device is a MOSFET.

In some implementations of the example power semiconductor device, the semiconductor device is a Schottky diode.

In some implementations of the example power semiconductor device, the semiconductor device is an IGBT.

In an aspect, the present disclosure provides an example power semiconductor device. In some implementations, the example power semiconductor device includes a silicon carbide semiconductor structure. In some implementations, the example power semiconductor device includes a drift region in the silicon carbide semiconductor structure. In some implementations, the example power semiconductor device includes an active structure in the silicon carbide semiconductor structure. In some implementations, the example power semiconductor device includes a heterodoped layer in the silicon carbide semiconductor structure. The heterodoped layer includes a first layer having a first dopant concentration of a first conductivity type. The heterodoped layer includes a second layer having a second dopant concentration of the first conductivity type. The drift region has a third dopant concentration of the first conductivity type. The first dopant concentration and the second dopant concentration are different from the third dopant concentration.

In some implementations of the example power semiconductor device, the power semiconductor device further includes a current spreading layer.

In some implementations of the example power semiconductor device, the heterodoped layer is in the drift region.

In some implementations of the example power semiconductor device, the heterodoped layer is in the active structure.

In some implementations of the example power semiconductor device, the first layer has a thickness of about 10 nm to about 200 nm, wherein the first dopant concentration is at least 20 times greater than the second dopant concentration.

In some implementations of the example power semiconductor device, the first dopant concentration is in a range of about 20 times greater to about 60 times greater than the second dopant concentration.

In some implementations of the example power semiconductor device, the first dopant concentration is in a range of about 30 times greater to about 40 times greater than the second dopant concentration.

In some implementations of the example power semiconductor device, the first dopant concentration is in a range of about 30 times greater to about 35 times greater than the second dopant concentration.

In some implementations of the example power semiconductor device, the second layer has a second thickness that is greater than the first thickness of the first layers.

In some implementations of the example power semiconductor device, second thickness is at least twice the first thickness.

In some implementations of the example power semiconductor device, the semiconductor structure includes epitaxial silicon carbide.

In some implementations of the example power semiconductor device, the semiconductor device is a MOSFET.

In some implementations of the example power semiconductor device, the semiconductor device is a Schottky diode.

In some implementations of the example power semiconductor device, the semiconductor device is an IGBT.

In an aspect, the present disclosure provides an example power semiconductor device. In some implementations, the example power semiconductor device includes a silicon carbide semiconductor structure. In some implementations, the example power semiconductor device includes a drift region in the silicon carbide semiconductor structure. In some implementations, the example power semiconductor device includes an active structure in the silicon carbide semiconductor structure. In some implementations, the example power semiconductor device includes a first layer having a compensating component in the silicon carbide semiconductor structure, a concentration of the compensating component being in a range of about 1×10¹⁷/cm³ to about 2×10²¹/cm³. In some implementations, the compensating component includes one or more of germanium, phosphorus, tin, or arsenic.

In some implementations of the example power semiconductor device, the first layer is part of a heterodoped layer.

In some implementations of the example power semiconductor device, the first layer is in the drift region.

In some implementations of the example power semiconductor device, the first layer is in the active structure.

In some implementations of the example power semiconductor device, the first layer has a thickness of about 10 nm to about 200 nm.

In some implementations of the example power semiconductor device, the heterodoped layer includes a second layer having a concentration of the compensating component that is less than the concentration of the compensating component in the first layer.

In some implementations of the example power semiconductor device, the second layer has a second thickness that is greater than the first thickness of the first layers.

In some implementations of the example power semiconductor device, the second thickness is at least twice the first thickness.

In some implementations of the example power semiconductor device, the semiconductor structure includes epitaxial silicon carbide.

In some implementations of the example power semiconductor device, the semiconductor device is a MOSFET.

In some implementations of the example power semiconductor device, the semiconductor device is a Schottky diode.

In some implementations of the example power semiconductor device, the semiconductor device is an IGBT.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A power semiconductor device, comprising:
a silicon carbide semiconductor structure;
at least one heterodoped layer in the silicon carbide semiconductor structure,
wherein the heterodoped layer comprises a first layer having a first dopant concentration of a first conductivity type in a range of about 1×10¹⁷/cm³ to about 2×10²¹/cm³, wherein the first layer has a first thickness in a range of about 10 nanometers to about 200 nanometers.

2. The power semiconductor device of claim 1, wherein the heterodoped layer comprises a second layer.

3. The power semiconductor device of claim 2, wherein the second layer has a second dopant concentration in a range of about 1×10¹³/cm³ to about 5×10¹⁵/cm³.

4. The power semiconductor device of claim 2, wherein the second layer is undoped.

5. The power semiconductor device of claim 2, wherein the second layer has a second thickness that is greater than the first thickness of the first layer.

6. The power semiconductor device of claim 5, wherein the second thickness is at least twice the first thickness.

7. The power semiconductor device of claim 3, wherein the semiconductor structure comprises a drift region, wherein the drift region has a third dopant concentration of the first conductivity type, wherein the third dopant concentration is less than the first dopant concentration of the first layer and greater than the second dopant concentration of the second layer.

8. The power semiconductor device of claim 1, wherein the first layer comprises a compensating component.

9. The power semiconductor device of claim 1, wherein the semiconductor device is a MOSFET, a Schottky diode, or an IGBT.

10. A power semiconductor device, comprising:
a silicon carbide semiconductor structure;
at least one heterodoped layer in the silicon carbide semiconductor structure, wherein the heterodoped layer comprises a first layer having a first dopant concentration of a first conductivity type in a range of about 1×10¹⁷/cm³ to about 2×10²¹/cm³, wherein the heterodoped layer comprises a second layer, wherein the second layer is undoped.

11. The power semiconductor device of claim 10, wherein the second layer has a second thickness that is greater than a first thickness of the first layer.

12. The power semiconductor device of claim 11, wherein the second thickness is at least twice the first thickness.

13. The power semiconductor device of claim 10, wherein the semiconductor structure comprises a drift region, wherein the drift region has a third dopant concentration of the first conductivity type, wherein the third dopant concentration is less than the first dopant concentration of the first layer and greater than a second dopant concentration of the second layer.

14. The power semiconductor device of claim 10, wherein the first layer comprises a compensating component.

15. The power semiconductor device of claim 10, wherein the semiconductor device is a MOSFET, a Schottky diode, or an IGBT.

16. A semiconductor device, comprising:
a silicon carbide semiconductor structure;
a heterodoped lattice structure in the silicon carbide semiconductor structure, the heterodoped lattice structure comprising:
at least two first layers having a first dopant concentration of a first conductivity type in a range of about 1×10¹⁷/cm³ to about 3×10¹⁹/cm³, wherein each first layer has a thickness in a range of about 10 nanometers to about 200 nanometers;
at least two second layers having a second dopant concentration of a first conductivity type that is less than the first dopant concentration of the plurality of first layers;
wherein the at least two first layers and the at least two second layers are arranged in alternating manner through a thickness of the silicon carbide semiconductor structure.

17. The semiconductor device of claim 16, wherein the second dopant concentration is in a range of about 1×10¹³/cm³ to about 5×10¹⁵/cm³.

18. The semiconductor device of claim 16, wherein the at least two second layers are undoped.

19. The semiconductor device of claim 16, wherein the second thickness is at least twice the first thickness.

20. The power semiconductor device of claim 16, wherein the semiconductor device is a MOSFET, a Schottky diode, or an IGBT.
